(19) United States
(12) Patent Application Publication
(10) Pub. No.: US 2009/0205707 A1
(43) Pub. Date: Aug. 20, 2009

(54) SOLAR CELL AND METHOD FOR PRODUCING THE SAME

(75) Inventors: Yoshiaki IKENOUE, Yokohama-shi (JP); Naoki Fukunaga, Munakata-shi (JP); Hironao Shinohara, Ichihara-shi (JP); Hisayuki Miki, Chiba-shi (JP); Kenzo Hanawa, Ichihara-shi (JP); Hiroaki Kaji, Chiba-shi (JP); Hitoshi Yokouchi, Ichihara-shi (JP); Ryoko Konta, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/388,145

(22) Filed: Feb. 18, 2009

(30) Foreign Application Priority Data
Feb. 19, 2008 (JP) 2008-038007

(51) Int. Cl. H01L 31/00; H01L 21/306

(52) U.S. Cl. 136/255; 136/256; 438/694; 257/E21.294

(57) ABSTRACT

The object of the present invention is to provide a solar cell which is industrially beneficial and has high light conversion efficiency; and a method for producing a solar cell; and the present invention provides a solar cell comprising a substrate, a power generation layer for converting received light into electrical power, a translucent electrode, and another electrode, when light travels through each member from a first surface thereof, a surface opposite to the first surface is defined as a second surface, the power generation layer is formed at a second surface side of the substrate, the translucent electrode is formed on one surface of the power generation layer, and another electrode is formed on the other surface of the power generation layer, wherein the translucent electrode comprises hexagonal In₂O₃ crystal.

### BACKGROUND OF THE INVENTION

1. Field of the Invention

The present invention relates to a solar cell and a method for producing a solar cell. Specifically, the present invention relates to a solar cell having a laminate structure including a group III nitride semiconductor (this is also called “a group III nitride compound semiconductor”), which has excellent mass productivity and excellent properties as a solar cell, and also a method therefor.

Priority is claimed on Japanese Patent Application, No. 2008-038007, filed on Feb. 19, 2008, the contents of which are incorporated herein by reference in their entirety.

2. Description of the Related Art

Technology related to photovoltaic generation has been in development for about thirty years. Energy consumption is rapidly increasing worldwide. In contrast, although some countries did not agree, a decrease in emission of global greenhouse gases was established worldwide under the Kyoto Protocol. Thereby, natural energy, in particular, photovoltaic generation, has been focused on.

In particular, since subsidy has been started in many countries, the market for photovoltaic generation has rapidly expanded. Thereby, a problem occurs in that silicon cannot be supplied to the photovoltaic market regularly due to an increase in demand for silicon in the semiconductor industry.

Specifically, although the demand for a polycrystalline silicon type solar cell, which is the most commonly used product at the present time, is rapidly increasing, the crystalline silicon material is not presently produced according to needs, and therefore the resulting supply is an increasing concern. Therefore, there is a demand to produce a thinner silicon substrate.

As a thin-film solar cell, photovoltaic generation systems using an amorphous silicon thin film or a fine crystalline silicon thin film are well-known.

In addition, photovoltaic generation systems using a compound semiconductor thin film, for example CIS-based thin films which include mainly Cu-, In-, Se-, and CIGS-based thin films which further include Ga are receiving attention in the development field.

In addition, photovoltaic systems, which can make a substrate for photovoltaic generation devices flexible and use a dye sensitization type element which includes an Ru-based dye, or an organic thin film element, are now being examined.

However, in order to increase the market for such a thin film type photovoltaic generation system, there are serious problems to be solved, such as insufficient light conversion efficiency, and the high production costs.

Specifically, InGaP/GaAs-based multi-junction solar cells, which are already in practical use as an electrical power source of artificial earth satellites, etc. and include a GaAs tunnel junction layer, have superior light conversion efficiency compared to that of silicon-based solar cells. However, the production cost is considerably higher than that of the silicon-based solar cells. Therefore, InGaP/GaAs-based multi-junction solar cells are not generally used.

Examples of a method for producing a solar cell including such a compound semiconductor include a method for producing a solar cell by depositing a semiconductor multi-layer structure, which is required by the multi-junction solar cell, by the MOCVD method (Patent Document No. 1). In addition, three-terminal type multi-junction solar cells which are produced by layering a Ge layer as a lower cell and a GaAs layer as a upper cell by the MOCVD method similarly (Patent Document No. 2) are suggested. In addition, light-gathering photovoltaic generation devices, which are obtained by fixing a light-gathering device in InGaP/InGaAs/Ge type multi-junction solar cells, are also suggested (Patent Document No. 3).

Furthermore, multi-junction type solar cells having plural pn-junctions, which are obtained by growing an In_{(1-X)}Ga_{(X)}N-based thin film (Eg: about 0.7 eV˜3.4 eV), are also suggested. However, the production methods and properties of such multi-junction type solar cells are not clear (For example, Patent Document No. 4).

As explained above, various photovoltaic generation systems using such a compound semiconductor have been suggested. However, conventional photovoltaic generation systems using a compound semiconductor involve complex growing methods for the thin film of a solar cell device, and this involves high production costs. In addition, methods for increasing the size of substrates have never been suggested. Furthermore, the cost of electric power in the photovoltaic generation systems using the compound semiconductor is remarkably higher than that of devices using other energy sources. It is very hard to decrease the production cost of the photovoltaic generation systems to the same level as that of the polycrystalline silicon-based solar cells already used in practice.

In addition to these, examples of a compound semiconductor include group III nitride semiconductors. Examples of a method for the crystalline growth of a group III nitride semiconductor include the MOCVD method in which ammonia reacts with organic metal, such as gallium, an organic indium compound, at high temperatures; the MBE method; the sputtering method (For example, Patent Document No. 5, Non-Patent Documents Nos. 1 and 2). However, the MBE method or the sputtering method is not industrially used to grow crystals in compound semiconductor light-emitting devices and solar cell devices.

Examples of a well-known transparent electrode material used in thin-film solar cell devices include ZnO, SnO₂, indium tin oxide (abbreviated as “ITO” below), and indium-zinc-oxide (abbreviated as “IZO” below) (Patent Document No. 6). In contrast, it is well-known that when an IZO film is formed on a glass substrate, using a target including 90% by weight of In₂O₃ and 10% by weight of ZnO, the obtained IZO film is amorphous (Non-Patent Document No. 3).
[Patent Document No. 1] Japanese Unexamined Patent Application, Publication No. 2001-4445
[Patent Document No. 2] Japanese Unexamined Patent Application, Publication No. 2002-368238
[Patent Document No. 3] Japanese Unexamined Patent Application, Publication No. 2006-313810
[Patent Document No. 4] United States Patent Application, Publication No. 2004-0118451
[Patent Document No. 5] Japanese Unexamined Patent Application, Publication No. S60-39819
[Non-Patent Document No. 1] Yukiko Ushiku et al., Formation of a GaN thin-film by high frequency magnetron sputtering method (I), The 2nd, 21st century union symposium—Scientific technology and Human—(2003, Tokyo)
[Non-Patent Document No. 2] Akinori Asami et al., Growth of Si- or Mg-doped GaN single-crystalline layer by UHV the sputtering method, the 66th Japanese Society of Applied Physics, Academic Lecture Presentation, Proceedings (2005 Autumn University of Tokushima)

### SUMMARY OF THE INVENTION

The object of the present invention is to provide a solar cell which can solve the problems, is industrially beneficial, and has high light conversion efficiency; and a method for producing a solar cell.

Specifically, the present invention provides the following.
(1) A solar cell comprising a substrate, a power generation layer for converting received light into electrical power, a translucent electrode, and another electrode which forms a pair with the translucent electrode, wherein when light travels through each member from a first surface thereof, a surface opposite to the first surface is defined as a second surface, the power generation layer is formed at a second surface side of the substrate, the translucent electrode is formed on one surface of the power generation layer, and the another electrode is formed on the other surface of the power generation layer, wherein the translucent electrode comprises hexagonal In₂O₃ crystal.
(2) A solar cell according to (1), wherein the hexagonal In₂O₃ crystal is comprised in crystalline IZO, and the content of zinc in the crystalline IZO is in a range of from 1% by mass to 20% by mass as ZnO equivalent.
(3) A solar cell according to (1) or (2), wherein a thickness of the translucent electrode is in a range of from 35 nm to 10 μm.
(4) A solar cell according to any one of (1) to (3), wherein the power generation layer comprises a group III nitride semiconductor layer having a pn-junction, which includes a p-type group III nitride semiconductor layer and an n-type group III nitride semiconductor layer, on the second surface side of the substrate.
(5) A solar cell according to any one of (1) to (4), wherein the power generation layer comprises a group III nitride semiconductor layer having a pn-junction, a p-type group III nitride semiconductor layer and an n-type group III nitride semiconductor layer, wherein the power generation layer is formed on a buffer layer, which is made of a group III nitride semiconductor, the buffer layer is formed at the second surface side of the substrate, and at least one of the buffer layer and the group III nitride semiconductor layer has a compound semiconductor layer which is made by a sputtering method.
(6) A solar cell according to (5), wherein the power generation layer comprises plural pn-junctions made of group III nitride semiconductor layers with p-type layers and n-type layers.
(7) A solar cell according to (5) or (6), wherein the group III nitride semiconductor layer having a pn-junction is formed on the buffer layer, and the group III nitride semiconductor layer having a pn-junction is made of InₓGa₍₁₋ₓ₎N (0≦x<1).
(8) A solar cell according to any one of (1) to (7), wherein the substrate is a substrate made of at least one of quartz, glass, sapphire, SiC, silicon, zinc oxide, magnesium oxide, manganese oxide, zirconium oxide, manganese-zinc-iron oxide, magnesium-aluminum oxide, zirconium boride, gallium oxide, indium oxide, lithium-gallium oxide, lithium-aluminum oxide, neodymium-gallium oxide, lanthanum-strontium-aluminum-tantalum oxide, strontium-titanium oxide, and titanium oxide.
(9) A solar cell according to any one of (1) to (8), wherein a p-type electrode of the translucent electrode and an n-type electrode of the another electrode are formed partially or entirely on the group III nitride semiconductor layer having a pn-junction
(10) A solar cell according to any one of (1) to (9), wherein the buffer layer is made of AlN or GaN.
(11) A method for producing a solar cell comprising: when light travels through each member from a first surface thereof, a surface opposite to the first surface is defined as a second surface, the method comprising a step (a) for forming a power generation layer for converting light received into electrical power at a second surface side of the substrate; a step (b) for forming an electrode on a surface of the power generation layer; and a step (c) for forming a translucent electrode, which forms a pair with the electrode, at another surface of the power generation layer, wherein the step (c) comprises a step (c1) for layering an amorphous IZO (indium-zinc-oxide) film at a side of a p-type semiconductor layer which is included in the power generation layer; a step (c2) for etching the amorphous IZO film, and a step (c3) for thermally treating the etched amorphous IZO film to be crystallized.
(12) A method for producing a solar cell according to (11), wherein the step (c1) is carried out by the sputtering method.
(13) A method for producing a solar cell according to (12), wherein a temperature in the step (c3) is in a range of from 500 to 1,000° C.
(14) A method for producing a solar cell according to any one of (11) to (13), wherein the power generation layer is made of a nitride gallium-based compound semiconductor which is a group III nitride semiconductor.
(15) A method for producing a solar cell according to (14), wherein the amorphous IZO film is layered on the p-type semiconductor layer in the power generation layer.
(16) A method for producing a solar cell according to any one of (11) to (15), wherein the step (a) comprises a stop for forming at least one of the buffer layer and the III nitride semiconductor layer having a pn-junction by the sputtering method, the buffer layer is formed on the substrate and made of a group III nitride semiconductor, and the III nitride semiconductor layer having a pn-junction (n-type layer and p-type layer) is formed on the buffer layer.
(17) A method for producing a solar cell according to (16), wherein any one layer of the p-type group III nitride semiconductor layer and the n-type group III nitride semiconductor layer is formed by at least one method selected from the group consisting of a sputtering method, metalorganic chemical vapor deposition method (MOCVD method), molecular beam epitaxy method (MBE method), chemical beam epitaxy method (CBE method), and molecular layer epitaxy method (MLE method).
(18) A method for producing a solar cell according to (16) or (17), wherein the sputtering method is a method in which nitrogen in the state of plasma, radical, and atom is supplied to react with a group III element.
(19) A method for producing a solar cell according to any one of (16) to (18), wherein the method includes a first step for alternately repeating a process for supplying only a dopant element and a process for supplying simultaneously a compound including a group III element and a nitrogen material.
(20) A method for producing a solar cell according to (19), wherein the method comprises a second step for a thermal treatment after the first step.
(21) A method for producing a solar cell according to (20), wherein the temperature in the thermal treatment is in the range of from 300 to 1,200° C.
(22) A method for producing a solar cell according to (20) or (21), wherein the thermal treatment is carried out under an atmosphere which does not contain a hydrogen gas or a gas containing compounds having a hydrogen atom.
(23) A method for producing a solar cell according to any one of (19) to (22), wherein the dopant element is at least one selected from the group consisting of Si, Ge, and Sn.
(24) A method for producing a solar cell according to any one of (19) to (22), wherein the dopant element is at least one selected from the group consisting of Mg, and Zn.

Moreover, the solar cell according to the present invention can include any power generation layer. The kinds of the material used or the structure of the power generation layer are not limited.

When the translucent (transparent) electrode, which is comprised in the solar cell according to the present invention, includes hexagonal In₂O₃ crystal, the translucent electrode becomes a conductive translucent electrode having high translucency from the visible range to the ultraviolet range. Thereby, the solar cell according to the present invention has improved optical transparency as a light receiving element. That is, the solar cell according to the present invention has excellent power generation properties.

In addition, when the translucent electrode is formed at the second surface side of the substrate so as to contact to the p-type group III nitride semiconductor layer or the n-type group III nitride semiconductor layer, which has a pn-junction and constitutes the group III nitride semiconductor layer, it is possible to use the translucent electrode as an ohmic electrode having excellent translucency

In addition, when an amorphous IZO film having excellent etching properties is used as the translucent electrode, the translucent electrode can be easily formed in a desired shape. Furthermore, after etching the translucent electrode, when the amorphous IZO film is thermally treated to transfer the amorphous states to crystalline states, the translucency of the IZO film can be improved. Therefore, the solar cell of the present invention has the translucent electrode having an improved translucency. Therefore, the solar cell according to the present invention can efficiently absorb light, in particular, ultraviolet light and light in neighborhood regions.

When the buffer layer made of a group III nitride semiconductor is formed on the substrate, it is preferable that a base layer be formed on the buffer layer. In particular, it is preferable that the buffer layer and the base layer have a compound semiconductor layer made by the sputtering method. When the buffer layer and the base layer have a compound semiconductor layer made by the sputtering method, and conditions for forming the buffer layer and the base layer are adjusted to be optimized, penetration dislocation can be reduced. In particular, the buffer layer formed by the sputtering method has excellent in-plane uniformity, compared with the buffer layer formed by the MOCVD method. Thereby, the state of the buffer layer changes from polycrystal (for example, columnar crystals) to single crystal.

In addition, the base layer, which is formed by the sputtering method, has a half-value width in a rocking curve at (0002) plane of 100 arcseconds or less, and a half-value width in a rocking curve at (10-10) plane of 300 arcseconds or less. Thereby, the conversion efficiency of the solar cell can be improved.

According to the solar cell, and the method for producing a solar cell in the present invention, it is possible to enlarge the size of the substrate in the solar cell. Therefore, the production cost can be greatly reduced. In addition, a large sized solar cell for power generation can be obtained by combining a solar concentrator.

In addition, when the base layer is formed by the sputtering method, it is possible to produce a base layer having a half-value width in a rocking curve at (0002) plane of 100 arcseconds or less, and a half-value width in a rocking curve at (10-10) plane of 300 arcseconds or less. Thereby, the conversion efficiency of the solar cell can be improved.

In particular, when the power generation layer includes a buffer layer, which is formed on the substrate, and made of a group III nitride semiconductor, and a group III nitride semiconductor layer, which has a pn-junction and includes a p-type group III nitride semiconductor layer and an n-type group III nitride semiconductor layer, and the step (a) includes a step for forming at least one of the buffer layer and the III nitride semiconductor layer by the sputtering method, the substrate having a large area can be used. Therefore, it is possible to remarkably reduce the production cost, compared with the production method which produces a solar cell only by the MOCVD method.

In addition, the production method of the present invention using the sputtering method is easily combined with other methods, such as the MOCVD method, the MBE method, the CBE method, and the MLE method. Thereby, the production time can be reduced. That is, it is possible to increase the production efficiency.

When the production method for a solar cell according to the present invention uses the sputtering method, a film is easily formed by supplying nitrogen in the state of plasma, radical, or atom and using the nitrogen with the group III group element.

In addition, when the production method includes the first step for alternately repeating a process for supplying only a dopant element and a process for supplying simultaneously a compound including a group III element and a nitrogen material, and the second step for thermally treating after the first step, the III nitride semiconductor layer having excellent properties can be formed.

### BRIEF DESCRIPTION OF THE DRAWINGS

FIG. 1 is an example of a sectional view showing the solar cell including the GaN junction layer which was produced in Example 1 according to the present invention.

FIG. 2 is an example of a planar view showing the electrode structure in the solar cell which was produced in Example 1 according to the present invention.

FIG. 3 is an example of a sectional view showing the solar cell including Inₓ₁Ga₁₋ₓ₁N junction layer which was produced in Example 2 according to the present invention.

FIG. 4 is an example of a sectional view showing the solar cell having two junctions of a GaN junction layer and an Inₓ₂Ga₁₋ₓ₂N junction layer according to the present invention.

FIG. 5 is a graph that shows the relationship between the temperature in the thermal treatment to the IZO film and the sheet resistance in the IZO film.

FIG. 6 is a graph that shows the relationship between the temperature in the thermal treatment to the IZO film and the carrier concentration in the IZO film.

FIG. 7 is a graph that shows the relationship between the temperature in the thermal treatment to the IZO film and the carrier mobility in the IZO film.

FIG. 8 is a graph that shows X-ray analysis data (XRD) of the IZO film which was not subjected to the thermal treatment.

FIG. 9 is a graph that shows X-ray analysis data (XRD) of the IZO film which was subjected to the thermal treatment at 300° C.

FIG. 10 is a graph that shows X-ray analysis data (XRD) of the IZO film which was subjected to the thermal treatment at 400° C.

FIG. 11 is a graph that shows X-ray analysis data (XRD) of the IZO film which was subjected to the thermal treatment at 500° C.

FIG. 12 is a graph that shows X-ray analysis data (XRD) of the IZO film which was subjected to the thermal treatment at 600° C.

FIG. 13 is a graph that shows X-ray analysis data (XRD) of the IZO film which was subjected to the thermal treatment at 650° C.

FIG. 14 is a graph that shows X-ray analysis data (XRD) of the IZO film which was subjected to the thermal treatment at 700° C.

FIG. 15 is a graph that shows X-ray analysis data (XRD) of the IZO film which was subjected to the thermal treatment at 800° C.

FIG. 16 is a graph that shows X-ray analysis data (XRD) of the IZO film which was subjected to the thermal treatment at 900° C.

FIG. 17 is a graph that shows the relationship between the light transmittance and the transmittance wavelength in the IZO films, one of which was not subjected to the thermal treatment, and the others of which were subjected to the thermal treatment at a fixed temperate.

FIG. 18 is a graph that shows X-ray analysis data (XRD) of the ITO film which was subjected to the thermal treatment at 400° C.

FIG. 19 is a graph that shows X-ray analysis data (XRD) of the ITO film which was subjected to the thermal treatment at 600° C.

FIG. 20 is a graph that shows X-ray analysis data (XRD) of the indium-gallium-oxide (abbreviated as “IGO” below) film which was not subjected to the thermal treatment.

FIG. 21 is a graph that shows X-ray analysis data (XRD) of the IGO film which was subjected to the thermal treatment at 200° C.

FIG. 22 is a graph that shows X-ray analysis data (XRD) of the IGO film which was subjected to the thermal treatment at 400° C.

FIG. 23 is a graph that shows X-ray analysis data (XRD) of the IGO film which was subjected to the thermal treatment at 600° C.

### DETAILED DESCRIPTION OF THE INVENTION

As explained above, the present invention provides a solar cell comprising a substrate, a power generation layer for converting received light into electrical power, a translucent electrode, and another electrode, which forms a pair with the translucent electrode, when light travels through each member from a first surface thereof, a surface opposite to the first surface is defined as a second surface, the power generation layer is formed at a second surface side of the substrate, the translucent electrode is formed on one surface of the power generation layer, and the another electrode is formed on the other surface of the power generation layer, wherein the translucent electrode comprises hexagonal In₂O₃ crystal.

In the solar cell of the present invention, it is preferable that the hexagonal In₂O₃ crystal is included in at least one of the IZO containing zinc oxide, the ITO containing tin oxide, and the IGO containing gallium-oxide.

In general, the solar cells are roughly divided into bulk type solar cells, and thin film type solar cells. The type of the solar cell according to the present invention is not particularly limited. However, the solar cells according to the present invention are preferably used as a thin film type solar cell.

Below, a solar cell is explained as one embodiment of the present invention, which includes a buffer layer made of a group III nitride semiconductor; a base layer, and group III nitride semiconductor layers (p-type layer/n-type layer) having a pn-junction, which are layered on the second surface of the substrate, in this order. That is, the solar cell, in which the power generation layer is corresponding to the group III nitride semiconductor layers having a pn-junction, the power generation layer may include the buffer layer and the base layer with the layer having the pn-junction.

In the solar cell of the present invention, it is preferable that at least one of the buffer layer and the group III nitride semiconductor layer having a pn-junction have a compound semiconductor layer which is formed by the sputtering method.

In the solar cell of the present invention, it is preferable that the base layer be made of the group III nitride semiconductor.

In addition, in the solar cell of the present invention, it is also preferable that both of the base layer and the group III nitride semiconductor (p-type layer/n-type layer) be formed by the sputtering method.

In the solar cell of the present invention, the sequence in layering each layer constituting the group III nitride semiconductor having a pn-junction is not limited. However, it is preferable that the n-type group III nitride semiconductor and the p-type group III nitride semiconductor be formed in this order from an incident direction of light. In addition, a tandem structure including plural semiconductor layers having a pn-junction in the same plane may also be used.

The substrate may be a substrate made of the group III nitride semiconductor or a heterogeneous substrate made of a material which is different from a material crystal growing on the substrate.

Specifically, examples of the material constituting the heterogeneous substrate include quartz, glass, sapphire, SiC, silicon, zinc oxide, magnesium oxide, manganese oxide, zirconium oxide, manganese-zinc-iron oxide, magnesium-aluminum oxide, zirconium boride, gallium oxide, indium oxide, lithium-gallium oxide, lithium-aluminum oxide, neodymium-gallium oxide, lanthanum-strontium-aluminum-tantalum oxide, strontium-titanium oxide, and titanium oxide. Among these, at least one of quartz, glass, sapphire, SiC, and silicon is preferable. In addition, at least one of quartz, glass, and sapphire is more preferable.

The material constituting the buffer layer is not limited. However, GaN or AlN is preferable. In addition, the crystalline properties are not limited. The buffer layer may be made of polycrystal, such as columnar crystal, or single crystal. However, single crystal is preferable.

The thickness of the buffer layer is preferably in a range of from 1 nm to 1,000 nm, more preferably in a range of from 3 nm to 400 nm, and most preferably in a range of from 5 nm to 200 nm.

Before forming the buffer layer, the substrate may be put in a chamber of the sputtering device and be subjected to a pretreatment, for example, the substrate may be sputtered. Specifically, the pretreatment may be a treatment in which the substrate is subjected to Ar plasma or N₂ plasma in the chamber to clean the surface thereof. Organic material or oxide which is adhered on the surface of the substrate can be removed by applying Ar plasma or N₂ plasma. In this case, plasma particles work efficiently on the substrate by applying voltage between the substrate and the chamber without applying power to a target.

When the buffer layer is made by the sputtering method, the buffer layer having excellent uniformity can be produced. When the base layer is formed on the buffer layer having excellent uniformity, it is possible to reduce penetration dislocation in the base layer. In particular, the buffer layer made by the sputtering method has excellent in-plane uniformity even if it is thin, compared with the buffer layer formed by the MOCVD method.

In addition, in general, it is possible to lower the temperature of the substrate by the sputtering method. Therefore, even if a substrate made of material which is decomposed at high temperatures is used, it is possible to form a layer on the substrate without damage occurring.

The base layer is preferably made of InₓGa₍₁₋ₓ₎N (0≦x<1), and more preferably GaN. It is possible to dope an n-type impurity, if necessary. However, the base layer may be undoped (<1×10¹⁷/cm³). The base layer is preferably undoped, because excellent crystalline properties can be maintained. In addition, it is also possible to form an electrode on and under a pn-junction element by making the base layer conductive by doping a dopant.

The base layer is preferably formed on the buffer layer made by the sputtering method. When the base layer formed on the buffer layer is made by the sputtering method, the base layer has excellent properties; that is, a half-value width in a rocking curve at (0002) plane of 100 arcseconds or less, and a half-value width in a rocking curve at (10-10) plane of 300 arcseconds or less can be achieved.

The thickness of the base layer is not particularly limited. However, the thickness is preferably in a range of from 0.01 μm to 30 μm, more preferably in a range of from 0.05 μm to 20 μm, and most preferably in a range of from 0.1 μm to 10 μm.

Examples of the material constituting the power generation layer include silicon semiconductor in amorphous states, fine crystal states, or polycrystal states; compound semiconductors, such as CuInSe₂(including CuInGaSe₂ and CuInGaSe), a group II-V compound semiconductor, a group II-VI compound semiconductor, a group I-III-VI compound semiconductor, a group II-III-VI compound semiconductor, and a group III-VI compound semiconductor; and organic thin films. These can be used alone or in combination. As explained above, the power generation layer used in the solar cell according to the present invention is not limited to these materials.

In the solar cell of the present invention, the power generation layer is preferably the group III nitride semiconductor layer having a pn-junction, and more preferably InₓGa₍₁₋ₓ₎N (0≦x<1). Moreover, X denotes any atomic ratio in the chemical formula. For example, X denotes X1 or X2, which is explained below. Below, X denotes any atomic ratio, such as X1, and X2, similarly.

As explained above, the power generation layer may include only one group III nitride semiconductor layer having a pn-junction, or two or more. When the power generation layer includes plural group III nitride semiconductor layers, they may be connected by a tunnel junction or an ohmic electrode.

The electrode, which forms a pair with the translucent electrode, may be made of any well-known materials. For example, the electrode may be obtained by layering titanium, aluminum, or gold.

Moreover, it is known that the crystalline In₂O₃ has a bixbite crystalline structure or a hexagonal crystalline structure. In the present invention, as explained above, the translucent electrode includes hexagonal In₂O₃.

In addition, it is preferable that the crystalline IZO including the hexagonal In₂O₃ crystal uses as a translucent electrode.

It is also preferable that crystalline IZO have a composition such that the specific resistance is as low as can be. Specifically, the concentration of ZnO in the IZO is preferably in a range of from 1% by mass to 20% by mass, more preferably in a range of from 5% by mass to 15% by mass, and most preferably 10% by mass.

The thickness of the translucent electrode is preferably in a range of from 35 nm to 10,000 nm (10 μm), because it is possible to obtain a lower specific resistance and high light transmittance. From the viewpoint of the production cost, the thickness of the translucent electrode is preferably 1,000 nm (1 μm) or less.

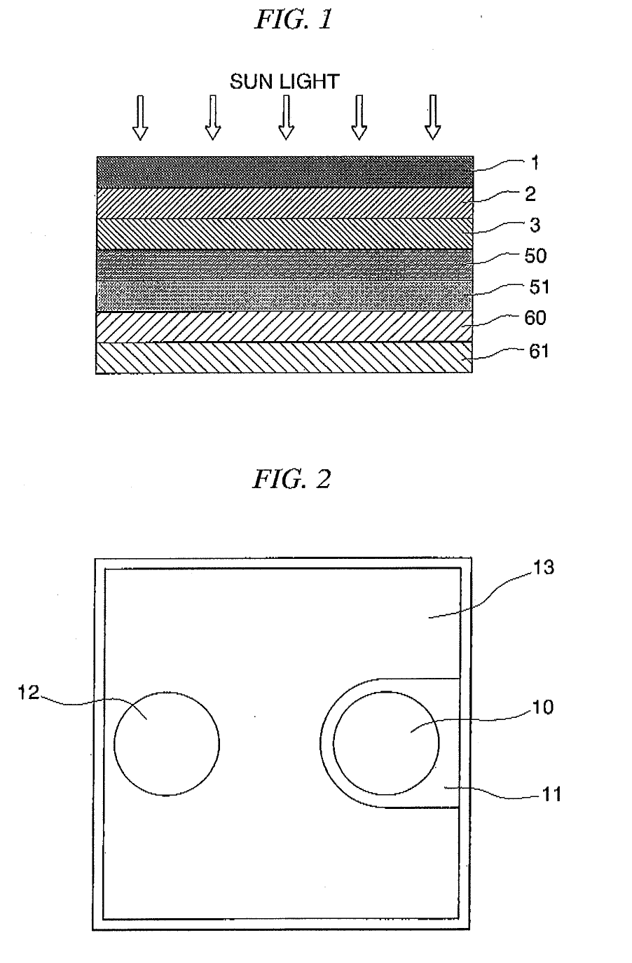

Below, the embodiments of the solar cell and the production method for a solar cell according to the present invention will be explained referring to figures. Although, the figures show a frame format of the solar cell, the thickness, size, etc. of each layer are not the same as those of the actual layer. In addition, the incident direction of light into the solar cell is not limited to the direction shown in FIGS. 1, 3, and 4. Light can enter into the solar cell in a different direction from that shown in FIGS. 1, 3, and 4. Moreover, when light travels through each member from a first surface thereof a surface opposite to the first surface is defined as a second surface in the following embodiments.

FIG. 1 is a sectional view showing the solar cell including the power generation layer, which is the GaN junction layer, produced in Example 1 according to the present invention.

The solar cell shown in FIG. 1 includes a substrate 1 made of quartz, and a power generation layer. The power generation layer includes an AlN buffer layer 2 formed on the substrate 1, an undoped GaN base layer 3 formed on the buffer layer 2, and an n-type GaN layer 50 and a p-type GaN layer 51 which have a pn-junction. In addition, an ohmic electrode 60 is layered on the semiconductor layer which is the power generation layer. The ohmic electrode 60 is made of ITO. The surface of the ohmic electrode 60 is covered with the protective film 61, if necessary. Any material, the shape, etc. can be used in the protective film 61, as long as it can protect the ohmic electrode 60.

Furthermore, a well-known antireflection film, such as a MgF₂/ZnS₂ film, is formed on the first surface of the substrate 1.

As explained above, the ohmic electrode (ohmic contact electrode) 60, which is an ITO film, or an Au electrode, is formed on the surface of the p-type GaN layer 51. The n-type GaN layer 50 itself works as a contact layer. Therefore, the n-type GaN layer 50 is partially exposed by a well-known photolithograpy method or etching method including a dry-etching method, and an electrode pad is formed on the exposed surface. The electrode pad may be made of Cr, Ti, Au, etc.

It is preferable that the AlN buffer layer 2 shown in FIG. 1 be formed by the sputtering method. When the buffer layer 2 is made by the sputtering method, it is preferable that semiconductor layers other than the buffer layer 2 be formed by epitaxial-growth in the MOCVD method.

The n-type semiconductor can include any n-type dopant as long as the n-type semiconductor including the n-type dopant works to generate electric power. However, examples of the preferred n-type dopant include at least one of Si, Ge, and Sn. Similar to the n-type semiconductor, any p-type dopant can be used as long as the p-type semiconductor including the p-type dopant works to generate electric power. However, examples of the preferred p-type dopant include at least one of Mg and Zn.

The solar cells are joined, and they are used as a junction cell. The thickness of the solar cell according to the present invention is not particularly limited. However, the thickness of the solar cell is preferably in a range of from 0.1 μm to 3 μm.

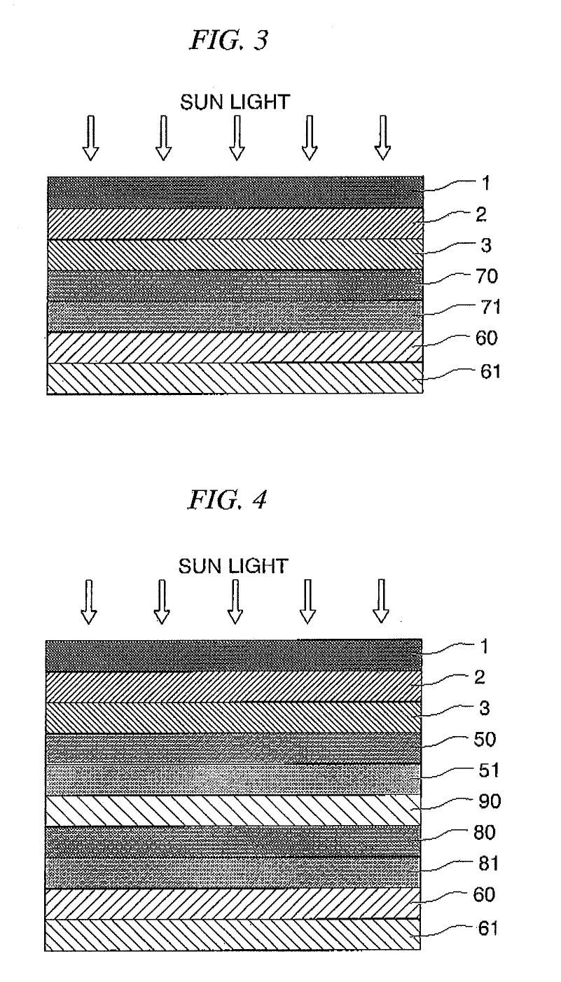

FIG. 3 is an example of a sectional view showing the solar cell including an n-type Inₓ₁Ga₁₋ₓ₁N layer 70 and a p-type Inₓ₁Ga₁₋ₓ₁N layer 71, which have a pn-junction, instead of the n-type GaN layer 50 and the p-type GaN layer 51, which have a pn-junction, used in the solar cell shown in FIG. 1.

The thickness of the n-type layer 70 and p-type layer 71, which are made of Inₓ₁Ga₁₋ₓ₁N (0≦x<1), is preferably in a range of from 20 nm to 1.5 μm, respectively. In addition, the concentration of impurities is preferably in a range of from 4×10¹⁷ cm⁻³ to 4×10¹⁸ cm⁻³.

The solar cell shown in FIG. 3 may be a laminate including plural compound semiconductor layers having a pn-junction as the power generation layer. In this case, it is preferable that the plural compound semiconductor layers be joined by a tunnel junction layer having a high tunnel peak current density.

In the solar cell shown in FIG. 3, the ohmic electrode (ohmic contact electrode) 60, which is an ITO film or an Au electrode, is formed on the p-type Inₓ₁Ga₁₋ₓ₁N layer 71.

The n-type Inₓ₁Ga₁₋ₓ₁N layer 70 itself works as a contact layer. Therefore, the n-type Inₓ₁Ga₁₋ₓ₁N layer 70 is partially exposed by a well-known photolithography method or etching method including a dry-etching method, and an electrode pad is formed on the exposed surface. The electrode pad may be made of Cr, Ti, Au, etc.

Similar to the solar cell shown in FIG. 1, it is preferable that the AlN butter layer 2 be formed by the sputtering method. When the buffer layer 2 is made by the sputtering method, it is preferable that semiconductor layers other than the buffer layer 2 be formed by epitaxially-growth in the MOCVD method.

In addition, the material for the n-type semiconductor layer 70 and the p-type semiconductor layer 71 may be the same materials used in the n-type and the p-type semiconductor layers shown in FIG. 1.

The solar cells are joined, and they are used as a junction cell. The thickness of the solar cell according to the present invention is not particularly limited. However, the thickness of the solar cell is preferably in a range of from 0.1 μm to 3 μm.

FIG. 4 is an example of a sectional view showing the solar cell including the n-type GaN layer 50 and the p-type GaN layer 51, which have a pn-junction, and the n-type Inₓ₂Ga₁₋ₓ₂N layer 80 and a p-type Inₓ₂Ga₁₋ₓ₂N layer 81, which have a pn-junction.

The thickness of the n-type layer 80 and p-type layer 81, which are made of Inₓ₂Ga₁₋ₓ₂N (0≦x₂<1), is preferably in a range of from 20 nm to 1.5 μm, respectively. In addition, the concentration of impurities is preferably in a range of from 4×10¹⁷ cm⁻³ to 4×10¹⁸ cm⁻³. The material for the n-type semiconductor layers 50 and 80 and the p-type semiconductor layers 51 and 81 may be the same materials used in the n-type and the p-type semiconductor layers shown in FIGS. 1 and 3.

Moreover, the reference number 90 in FIG. 4 denotes a tunnel junction layer made of InₓGa₁₋ₓN (23x<1). The compound semiconductor laminate can be formed in a similar way to the compound semiconductor laminate shown in FIGS. 1 and 3.

In the group III-V compound semiconductor, the temperature in which the group V elements are evaporated from the surface of the compound semiconductor layer is about 400° C. or greater. When the tunnel junction layer made of InₓGa₁₋ₓN (0≦x<1) is thermally treated under relatively high temperatures such as about 400° C. to 800° C. within a short time, such as several seconds, the tunnel peak current density of the tunnel junction layer can be improved to 50 mA/cm² or more. Of course, it is also possible to improve the tunnel peak current density by the thermal treatment at low temperatures, such as about 300° C. to 400° C. When the thermal treatment is carried out at low temperatures, the time of several dozen of minutes is needed. Since the tunnel junction layer also absorbs light, the tunnel junction layer is preferably thin as long as sufficient tunnel junction effects can be obtained. In other words, the thickness of the tunnel junction layer is preferably 10 nm or less.

The solar cells are joined, and they are used as a junction cell. The thickness of the solar cell according to the present invention is not particularly limited. However, the thickness of the solar cell is preferably in a range of from 0.1 μm to 3 μm.

As explained above, the method for producing the solar cell according to the present invention is a method, in which, when light travels through each member from a first surface thereof, a surface opposite to the first surface is defined as a second surface, the method including a step (a) for forming a power generation layer for converting light received into electrical power at a second surface side of the substrate; a step (b) for forming an electrode on a surface of the power generation layer; and a step (c) for forming a translucent electrode at another surface of the power generation layer, wherein the step (c) comprises a step (c1) for layering an amorphous IZO (indium-zinc-oxide) film at a side of a p-type semiconductor layer which is included in the power generation layer; a step (c2) for etching the amorphous IZO film, and a step (c3) for thermally treating the etched amorphous IZO film to be crystallized.

Below, the method for producing the solar cell will be explained in detail.

First of all, as explained above, the AlN layer is formed on the substrate by the sputtering method. After that, the base layer is formed on the AlN layer by the sputtering method, the MOCVD method, etc. Then, the group III nitride semiconductor layer having a pn-junction is formed on the base layer.

When the doped group III nitride semiconductor layer having a pn-junction is formed by the sputtering method, it is preferable to alternately form a layer made of the dopant atom and a layer made of an undoped group III nitride semiconductor.

When the chemical vapor layering method, such as the MOCVD method is used, doping can be carried out by mixing the dopant in gas. However, when the sputtering method is used, such a troublesome operation is not needed. Therefore, the sputtering method can solve the problems of the MOCVD method, such as productivity, and repeatability.

In physical method for producing a film made of crystal using the sputtering method, nitrogen is made plasma, radical, or atom, and then this is supplied. In order to prevent the reaction between the dopant atoms and nitrogen, it is preferable that nitrogen be not supplied in a chamber in a process for supplying the dopant atoms.

Examples of a method for supplying nitrogen in plasma or radical conditions include the sputtering method, the pulsed laser deposition method (PLD method), the pulsed electron beam deposition method (PED method), and the chemical vapor deposition method (CVD method). Among these, the sputtering method is simple and has excellent productivity. Therefore, the sputtering method is preferable. Since the DC sputtering method involves charge up at the surface of a target, and the film formation ratio may not be stable. Therefore, the pulse DC sputtering method or the RF sputtering method is preferable.

Well-known nitrogen sources can be used without any limitations. However, ammonia and nitrogen are preferable, because they are easily obtained at comparatively low price, and have easy handling.

Ammonia has improved decomposition efficiency, and can form a layer with a high growth rate. However, ammonia has high reactivity and toxicity. Therefore, it is necessary to provide toxic material elimination equipment or a gas detector. It is also necessary to make the reaction apparatus with materials which have high chemical stability.

In contrast, when nitrogen (N₂) is used as a raw material, a simple apparatus can be used. However, high reaction rate is not obtained. However, when nitrogen is introduced into the apparatus after decomposition by an electrical field or heat, a film formation rate which is lower than that of ammonia but sufficient in industrial production can be achieved. Therefore, when both the cost for the apparatus and the industrial production are concerned, nitrogen is the most preferably used as a nitrogen source.

In the method for producing a solar cell according to the present invention, it is preferable that a process for supplying only a dopant and a process for making a film made of a compound including a group III element using nitrogen be alternatively repeated. That is, it is preferable the production method of the present invention include a first step for alternately repeating a process for supplying only a dopant element and a process for supplying simultaneously a compound including a group III element and nitrogen.

The laminate, which is obtained by the production method including the first step, has a layer made of only the dopant and the undoped group III nitride semiconductor layer, which are layered alternately. When the layers are alternately formed, the dopant atoms constituting the dopant layer may be partially dispersed in the group III nitride semiconductor layer. However, the layer made of only the dopant is certainly obtained.

The dopant used may be a p-type dopant or a n-type dopant. Examples of the p-type dopant used in the group III nitride semiconductor include Mg and Zn. Examples of the n-type dopant include Si, Ge, and Sn. Among these, Si is preferably used as the n-type dopant, and Mg is preferably used as the p-type dopant. These have high doping efficiency and activation rate, and do not induce deteriorate of crystalline properties.

The thickness of the dopant layer made of only the dopant is preferably in a range of from 0.1 nm to 10 nm. When it is less than 0.1 nm, the dopant may not be sufficiently dispersed. In contrast, when it exceeds 10 nm, even if the group III nitride semiconductor crystal grows in the horizontal direction to the thickness of the layer, it is impossible to completely cover the surface of the dopant layer. The more preferable thickness is in a range of from 0.5 nm to 5 nm.

Moreover, since the crystal lattice constant of the dopant and the group III nitride semiconductor are different, when the dopant layer cover completely the group III nitride semiconductor layer, they do not have an epitaxial relationship. Due to this, the crystalline properties are decreased. Therefore, it is preferable that the dopant layer be sprinkled in an island shaped no so as to be a perfect layer. When the dopant layer is formed so as to contain sprinkled aggregations in an island shape, the crystal of the group III nitride semiconductor grows by originating from the exposed surface of the lower group III nitride semiconductor layer. Then, the group III nitride semiconductor grows in the horizontal direction to the thickness of the layer, and completely covers the surface of the dopant layer.

The interval between the dopant in an island shaped is preferably in a range of from 2 nm to 100 nm, and more preferably in a range of from 10 nm to 50 nm. When it is less than 2 nm, it is difficult for the group III compound semiconductor crystal to originate from the interval and epitaxially grow. In contrast, when it exceeds 100 nm, the dopant is not sufficiently dispersed. Thereby, driving voltage of the solar cell increases.

The area ratio of the dopant layer in an island shaped relative to the total area of the group III nitride semiconductor on which the dopant layer is formed is preferably in a range of from 0.001 to 0.9, and more preferably in a range of from 0.005 to 0.5. When it exceeds 0.9, it is difficult for the group III compound semiconductor crystal to originate from the interval and epitaxially grow. In contrast, when it is less than 0.001, the dopant is not sufficiently dispersed. Thereby, driving voltage of the solar cell increases.

The diameter (the diameter of a circle, when the shape of sprinkled aggregations which constitutes the dopant layer, is portray as a circle) of each aggregation is preferably in a range of from 0.5 nm to 100 nm, and more preferably in a range of from 1 nm to 10 nm. When it is less than 0.5 nm, the dopant is not sufficiently dispersed. Thereby, driving voltage of the solar cell increases. In contrast, when it exceeds 100 nm, the crystalline properties of the group III compound semiconductor crystal decrease.

The diameters and intervals of the dopant layer in an island shaped can be measured by observing a sample obtained by cutting to expose the cross section of the dopant layer. In addition, the area ratio of the dopant layer in an island shaped relative to the total area can be calculated, for example, by randomly selecting ten dopant islands, measuring the diameter and the interval of the ten dopant islands, and calculating the average value.

The dopant layer in an island shaped can be formed by adjusting the conditions for forming the dopant layer. The dopant layer and the group III nitride semiconductor layer do not make lattice junction. Therefore, when the dopant layer is made under conditions in which migration is actively generated, the crystalline agglomerates in an island shaped can be formed.

For example, the dopant layer in an island shaped can be formed under conditions in which the substrate temperature is 600° C. or greater, the chamber pressure is 0.3 Pa or less, and the formation ratio is 0.5 nm/sec or less.

In contrast, the group III nitride semiconductor crystal constituting the group III nitride semiconductor is preferably InₓGa₁₋ₓN (0≦x<1).

The thickness of the group III nitride semiconductor layer is preferably in a range of from 1 nm to 500 nm, and more preferably in a range of from 10 nm to 100 nm. When it exceeds 500 nm, the dopant may be sufficiently dispersed. In contrast, when it is less than 1 nm, it is difficult to grow the group III compound semiconductor crystal in the horizontal direction to the thickness of the layer to fill the intervals between the dopant layer in an island shaped.

In addition, the thickness ratio (the III nitride semiconductor layer/the dopant layer) between the group III nitride semiconductor layer and the dopant layer is preferably in a range of from 10 to 1,000. When it is less than 10, since the amount of dopant is too much, the crystalline properties of the group III nitride compound semiconductor decrease. In contrast, when it exceeds 1,000, the dopant is not sufficiently dispersed. Thereby, resistance of the laminate is increased. Due to this, driving voltage of the solar cell increases

The repeating number for forming the group III nitride semiconductor layer and the dopant layer is preferably in a range of from 1 to 200. When it exceeds 200, there is no large difference in effects obtained, and it involves a decrease of crystalline properties.

Moreover, as explained above, the power generation layer is preferably formed by the sputtering method. In other words, at least one of the buffer layer, the base layer, the n-type group III nitride semiconductor layer, the p-type group III nitride semiconductor, and the dopant layer, is preferably formed by the sputtering method.

When the layer is formed by the sputtering method, the important parameters are the substrate temperature, the pressure in the furnace, and the nitrogen partial pressure. In general, the substrate temperature is in a range of from room temperature to 1,200° C., and preferably 200° C. to 900° C. When it exceeds 1,200° C., the crystal is decomposed.

The pressure inside the furnace is preferably 0.3 Pa or greater. When it is less than 0.3 Pa, since the amount of nitrogen is small, and metal sputtered adheres without becoming nitride. There is no upper limitation of the pressure inside the furnace. However, it is needless to say that the pressure for generating plasma is necessary.

The flow rate of nitrogen relative to the total flow of nitrogen and argon is preferably in a range of from 20% by volume to 100% by volume, and more preferably in a range of from 50% by volume to 90% by volume. When it is less than 20% by volume, metal sputtered adheres keeping metal conditions. When it exceeds 90% by volume, the amount of argon is small, there is a tendency that the sputtering speed decreases.

The film formation speed is preferably in a range of from 0.01 nm/sec. to 10 nm/sec. When it exceeds 10 nm/sec, the film becomes amorphous without becoming crystals. In contrast, when it is less than 0.01 nm/sec, the layer has an island shape, not a film. Due to this, it is impossible to cover the substrate.

Moreover, since the dopant layer contains only one component, the dopant layer is not formed by the reactive the sputtering method. However, both the RF sputtering method and the DC sputtering method can be used. When the DC sputtering method is used, it is preferable to apply conductive properties, to a target not so as to be charged. For example, when Si having high purity is used, since Si is insulating, charge-up may be caused. Therefore, it is preferable to dope Si with B or P. However, when the wafer is alternately transfer between chambers during formation of the dopant layers and the group III nitride semiconductor layers, it is a waste of time. Therefore, it is preferable to form the dopant layer in the same chamber for forming the group III nitride semiconductor. As a result, the RF sputtering method is preferably used to form the dopant layer.

The preferable pressure inside the chamber and the substrate temperature during formation of the dopant layer are the same those for formation of the group III nitride semiconductor layer. However, the film formation speed is preferably in a range of from 0.001 to 1 nm/sec, because the thickness of the dopant layer, which is thinner than the group III nitride semiconductor layer, can be properly adjusted.

After formation of the laminate in which the dopant layer and the group III nitride semiconductor layer are alternately layered, it is preferable to carry out a thermal treatment as a second step. When the laminate is subjected to the thermal treatment, it is possible to disperse the dopant into the group III nitride semiconductor crystals. Thereby, more stable dopant conditions can be obtained.

The temperature in the thermal treatment is preferably 300° or greater. In particular, there is no upper limitation. However, it is needless to say that the upper temperature is less than the temperature in which the matrix crystals are decomposed. Almost all of the group III nitride semiconductor crystals may be decomposed at about 1,200° C.

The treatment time is not particularly limited. However, the treatment time is generally in a range of from 30 seconds to 1 hour. When it is less than 30 seconds, the effects obtained by the thermal treatment are insufficient. In contrast, when it exceeds 1 hour, the effects obtained is not changed, and it is waste of time.

In particular, when the p-type laminate including the p-type dopant layer is needed, the atmosphere gas in the thermal treatment preferably does not contain hydrogen gas or a compound gas including a hydrogen atom. In particular, it is preferable that H₂ gas or NH₃ gas which is known as a gas generating H₂ gas by decomposition at high temperatures be not used.

The laminate after the thermal treatment may contain dopant agglomerates as a trace of the dopant layer depending on the time and the temperature in the thermal treatment. In addition, although the dopant agglomerates are dispersed and disappeared, a layer having a high concentration of the dopant and a layer having a low concentration of the dopant may be repeatedly formed. Furthermore, the dopant layer, in which the dopant is completely dispersed uniformly, may be obtained.

As a result, the laminate after the thermal treatment works as a contact layer. Of course, when the p-type dopant layer is formed, the p-type contact layer is obtained. When the n-type dopant layer is formed, the n-type contact layer is obtained.

An electrode for passing current can be formed on the contact layer. Any materials as the material for the electrode include can be used without any limitations. Examples of the material for the electrode include n-type electrode materials, such as Al, Ti, Cr, and p-type electrode materials, such as Ni, Au, and Pt. In addition, conductive oxides such as ITO, ZnO, ZnO-Al₂O₃ (abbreviated as “AZO” below), and IZO can also be used.

In the solar cell according to the present invention, it is preferable that the translucent electrode is formed on the first surface of the power generation layer, the translucent electrode contain hexagonal In₂O₃ crystal, and the hexagonal In₂O₃ crystal contain IZO. Specifically, the translucent electrode can be formed by forming an amorphous IZO film on the entire surface of the p-type semiconductor layer.

Any forming film methods, which are well-known as a method for producing a thin film, can be used to the IZO film as long as it can form an amorphous IZO film. For example, the sputtering method, the vacuum vapor deposition method can be used. However, since the sputtering method provides less amount of particles or dust than that of the vacuum vapor deposition method, the sputtering method is preferably used.

When the sputtering method is used to make the amorphous IZO film as the translucent electrode, it is preferable that the RF magnetron sputtering method is used and an In₂O₃ target and a ZnO target be revolted. However, when a film formation speed is wanted to be more improved, it is preferable that the DC magnetron sputtering method be used, and an IZO target be used. In addition, in order to decrease the damage to the p-type semiconductor layer due to plasma, the discharge power in the sputtering method is preferably 1,000 W or less.

In this way, the translucent electrode, which is an amorphous IZO film, is formed on the entire surface of the p-type semiconductor layer. Then, the area other than the area, at which a positive electrode is formed, is patterned to remove by the well-known photolithography method and etching method. Thereby, the translucent electrode 13 is formed on the area, at which the positive electrode is formed, as shown in FIG. 2. The translucent electrode 13 is preferably an ohmic electrode.

Moreover, the patterning of the IZO film is preferably carried out before the thermal treatment which is explained in detail below. The reasons are that the amorphous IZO film changes to crystalline IZO film by the thermal treatment, and it is difficult to etch the crystalline IZO film, compared with the amorphous IZO film. The amorphous IZO film can be easily etched using a well-known etchant with a high accuracy. Specifically, when ITO-07N etchant marketed by Kanto Chemical Co., Inc. is used, the amorphous IZO film can be etched with an etching speed of about 40 nm/min. In addition, burr and over etching are hardly generated.

In addition, the amorphous IZO film can be etched using a dry-etching device. When a dry-etching device is used, Cl₂, SiCl₄, BCl₃, etc. can be used as an etching gas.

It is possible to form a patterned indented surface in the amorphous IZO film using the photolithography method the etching method. For example, when the ITO-07N etchant is used, it is possible to form a patterned indented surface having a depth of 40 nm by etching for one minute.

The process for forming a patterned indented surface in the amorphous IZO film is preferably carried out before the thermal treatment, similar to the patterning.

The amorphous IZO film cam be changed to the IZO film containing hexagonal In₂O₃ crystal by a thermal treatment at 500° C. to 1,000° C. under controlled conditions. The IZO film containing hexagonal In₂O₃ crystal has extremely high light transmittance, in particular, in 380 nm to 500 nm. Therefore, the amorphous IZO film has excellent properties as the translucent electrode in the solar cell. The solar cell including the amorphous IZO film as the translucent electrode can effectively absorb light around ultraviolet ray and its neighborhood light.

The thermal treatment for the amorphous IZO film is explained below.

The IZO film containing hexagonal In₂O₃ crystal can be prepared by subjecting the amorphous IZO film to the thermal treatment.

The conditions in the thermal treatment vary depending on the film formation method and the composition of the IZO film. For example, the temperature for crystallizing is lowered by decreasing the concentration of zinc (Zn) in the IZO film. Therefore, the IZO film having hexagonal In₂O₃ crystal can be obtained by the thermal treatment at lower temperatures.

Moreover, the thermal treatment is carried out to crystallize the amorphous IZO film and obtain the IZO film containing hexagonal In₂O₃ crystal. However, any method can be used in the present invention as long as it can crystallize the amorphous IZO film and obtain the IZO film containing hexagonal In₂O₃ crystal. For example, a rapid thermal annealing method (RTA annealing method), a laser annealing method, an electron beam irradiation method, etc. can be used.

Moreover, in the method for producing a solar cell according to the present invention, the IZO film may contain bixbite In₂O₃.

In addition, the IZO film, which is crystallized by the thermal treatment, has improved adhesion to the p-type semiconductor layer and the positive electrode, compared to the amorphous IZO. Therefore, it is possible to prevent the decrease of yield of the defective solar cell due to the peeling of the IZO film during the manufacture. The IZO film containing hexagonal In₂O₃ crystal has lower reactivity to moisture in air, superior chemical resistance, such as acid resistance, and less degradation of properties in an endurance test for a long time, compared with the amorphous IZO film. Therefore, the IZO film, which is crystallized by the thermal treatment, is preferable.

The thermal treatment for the amorphous IZO film is preferably carried out under conditions that do not contain O₂. Specifically, the thermal treatment is preferably carried out under conditions, such as inert gas atmosphere, such as N₂, a mixed gas of inert gas, such as N₂ and H₂. The thermal treatment is more preferably carried out under inert gas atmosphere, such as N₂ gas, or a mixed gas atmosphere, such as H₂ and inert gas such as N₂.

When the IZO film is thermally treated under N₂ gas atmosphere, or a mixed gas atmosphere containing N₂ and H₂, the sheet resistance of the IZO film can be effectively reduced, together with obtaining the IZO film containing hexagonal In₂O₃ crystal. In particular, when the sheet resistance is wanted to be reduced, it is preferable that the thermal treatment be carried out under a mixed gas atmosphere containing N₂ and H₂. The ratio (N₂:H₂) between N₂ and H₂ in the mixed gas is preferably in a range of from 100:1 to 1:100.

The temperature in the thermal treatment for the IZO film is preferably in a range of from 500° C. to 1,000° C. When the temperature is less than 500° C., the IZO film may not sufficiently crystallized, and the light transmittance may not be sufficiently improved. In contrast, it exceeds 1,000° C., the IZO film can be crystallized, but the light transmittance may not be sufficiently improved. In addition, the semiconductor layer, which is under the IZO film, may be deteriorated.

Moreover, when the amorphous IZO film is crystallized, the crystalline structure in the IZO film varies depending on the film formation conditions and the thermal treatment conditions.

In particular, the carrier mobility in the IZO film is preferably in a range of from 30 cm²/V·sec to 100 cm²/V·sec, more preferably 35 cm²/V·sec or more, and most preferably 38 cm²/V·sec or more.

When the carrier mobility in the IZO film is adjusted in the range, the translucent electrode, which has remarkably high light transmittance in ultraviolet ray range and its neighborhood light rage, can be obtained. Thereby, the solar cell having excellent properties can be obtained.

Moreover, “carrier mobility” in the present invention denotes the value which is obtained by dividing the mobile speed of charged particles, that is, the mobile speed of carrier in an electrical filed by the intensity of the electrical filed.

In addition, the carrier concentration in the IZO film is not particularly limited, but it is preferable in a range of from 1×10²⁰ cm⁻³ to 5×10²¹ cm⁻³.

The sheet resistance of the IZO film is preferably 50 Ω/sq or less, and more preferably 20 Ω/sq or less, in order to effectively disperse current.

The thickness of the IZO film is preferably in a range of from 35 nm to 10,000 nm (10 μm) in which low sheet resistance and high light transmittance can be obtained. From the viewpoint of the production cost, the thickness of the positive electrode is preferably 1,000 nm (1 μm) or less.

### EXAMPLE

Next, the solar cell and the production method for a solar cell according to the present invention are explained in detail referring to Examples and Evaluation Tests. However, the present invention is not limited to the following Examples.

### Example 1

In Example 1, the solar cell including the laminate shown in FIG. 1 was produced.

First of all, the AlN buffer layer 2 having a thickness of 30 nm, and the undoped GaN base layer 3 having a thickness of 0.1 μm were layered on the quartz glass substrate 1. The used quartz glass is a commercially available optical material, and has a square size of 30 cm.

Specifically, the AlN buffer layer 2 was layered on the substrate 1 by hitting an Al target with argon plasma to beat out Al atoms, and making the Al atoms react with nitrogen, while introducing a mixed gas containing argon and nitrogen into a chamber and using nitrogen plasmas, which were obtained by applying an electrical field.

In a similar way to the AlN buffer layer 2, the undoped GaN base layer 3 was layered on the AlN buffer layer 2 by hitting a Ga target with argon plasmas to beat out Ga atoms, and making the Ga atoms react with nitrogen, while introducing a mixed gas containing argon and nitrogen into the chamber and using nitrogen plasma, which was obtained by applying an electrical field.

Then, an n-type GaN layer 50 having a thickness of about 0.5 μm was obtained by alternately layering forty times a dopant layer, which contains Si crystalline aggregations having an island shape, and has a thickness of 2 nm, and an undoped GaN layer which has a thickness of 100 nm, and then thermally treated.

Specifically, the undoped GaN layer was formed by the same processes as those of the undoped GaN base layer 3. After that, the dopant layer containing sprinkled Si crystalline aggregations having an island shape was obtained by introducing only argon gas into the chamber, and layering Si atoms, which were obtained by hitting the Si target with argon plasmas, on the undoped GaN layer. These processes were repeated forty times to prepare the n-type GaN layer 50.

After that, in a similar way to the n-type GaN layer 50, a p-type GaN layer 51 having a thickness of about 0.5 μm was obtained by alternately layering forty times a dopant layer, which contains sprinkled Mg crystalline aggregations, and has a thickness of 2 nm, and an undoped GaN layer which has a thickness of 100 nm, and then thermally treated.

Specifically, the undoped GaN layer was formed by the same processes as those of the undoped GaN base layer 3. After that, the dopant layer containing sprinkled Mg crystalline aggregations having an island shape was obtained by introducing only argon gas into the chamber, and layering Mg atoms, which were obtained by hitting the Mg target with argon plasma, on the undoped GaN layer. These processes were repeated forty times to prepare the p-type GaN layer 51.

These layers were prepared by the RF magnetron sputtering method. In the sputtering device used, the distance between the target and the cathode was 50 mm, the temperature of the substrate was 750° C., and the pressure inside the chamber was adjusted to 0.6 Pa.

The carrier concentration of the obtained n-type GaN layer 50 and p-type GaN layer 51 was about 2×10¹⁸ atoms/cm³.

After that, the substrate including the laminate was removed from the sputtering device, and put into an annealing furnace in order to carry out the thermal treatment. The temperature was adjusted to 1,100° C. and the treatment was carried out for 10 minutes. The atmosphere gas in the thermal treatment was only nitrogen.

The cross section of the n-type GaN layer 50 before and after the annealing was observed using a transmittance-type electronic microscope.

As a result of the observation, a structure, in which the dopant layer having a thickness of 2 nm, and the undoped GaN layer having a thickness of 100 nm are repeated alternately forty times, could be clearly confirmed in the laminate before the annealing. The dopant layer was partially divided and has an island shape, not a perfect layer. The diameter of each aggregation was about 1 nm, and the interval between aggregations was about 50 nm. The ratio of the total area of the dopant layer relative to the area of the surface of the undoped GaN layer was about 0.02.

The n-type Gan layer 50 after the annealing did not have a layered structure. Si atoms constituting the dopant layer were dispersed. It was believed that the Si atoms uniformly doped in the GaN layer.

Then, an ohmic electrode 60, which is an IZO film, was formed on the p-type GaN layer 51 in the laminate using a well-known photolithography. After that, an electrode, which forms a pair with the translucent electrode, was formed on the ohmic electrode 60 by laminating titanium, aluminum, and gold in this order.

Then, the obtained laminate was etched from the electrode side. The n-type GaN layer 50 was partially removed, to expose an area at which a negative electrode should be formed. The negative electrode which includes a Ni layer, an Al layer, a Ti layer, and an Au layer, was formed on the exposed area.

Then, the obtained IZO film was thermally treated at 800° C. for one minute under N₂ atmosphere to form the IZO film containing hexagonal In₂O₃ crystal. Thereby, the solar cell element was obtained in this Example.

The obtained solar cell element was divided into squares in 1 cm×1 cm. The electrodes were electrically connected to a lead frame using an Au wire to form a solar cell in Example 1. The planar view of the obtained solar cell is shown in FIG. 2.

### Example 2

The laminate shown in FIG. 1 was produced by a method which is different from the method in Example 1.

The AlN buffer layer 2 having a thickness of 30 nm was formed on the quartz substrate 1 by the RF magnetron sputtering method. Then, the substrate was removed from the sputtering device, and subjected a thermal treatment in an annealing furnace at 1,100° C. for 10 minutes under nitrogen atmosphere. After that, the substrate was introduced into the MOCVD furnace, and the p-type GaN layer 51, which was doped with Mg, was formed so as to prepare the laminate obtained in Example 1.

During the MOCVD method, common temperature, pressure, gas used, etc., were adopted.

The carrier concentration of the n-type GaN layer 50 and the p-type GaN layer 51 was about 2×10¹⁸ atoms/cm³.

Then, the solar cell element was obtained using the obtained laminate, in a similar way to Example 1. The obtained solar cell element was divided into squares in 1 cm×1 cm. The electrodes were electrically connected to a lead frame using an Au wire to form the solar cell in Example 2.

### Example 3

In Example 3, the solar cell including the laminate shown in FIG. 3 was produced.

First of all, an AlN buffer layer 2 having a thickness of 30 nm was formed on the quartz substrate 1 by the RF magnetron sputtering method. Then, the substrate was removed from the sputtering device, and subjected a thermal treatment in an annealing furnace at 1,100° C. for 10 minutes under nitrogen atmosphere. After that, the substrate was introduced into the MOCVD furnace. Then, the laminate, which includes the undoped GaN layer 3 having thickness of 6 μm, the n-type Inₓ₁Ga₁₋ₓ₁N layer 70 (X1=0.09) having a thickness of 0.1 nm, and the p-type Inₓ₁Ga₁₋ₓ₁N layer 71 (X1=0.09) having a thickness of 0.2 μm, was formed on the AlN buffer layer 2.

The carrier concentration of the n-type Inₓ₁Ga₁₋ₓ₁N layer 70 and the p-type Inₓ₁Ga₁₋ₓ₁N layer 71 was about 3×10¹⁸ atoms/cm³.

Then, the solar cell element was obtained using the obtained laminate, in a similar way to Example 1. The obtained solar cell element was divided into squares in 1 cm×1 cm. The electrodes were electrically connected to a lead frame using an Au wire to form the solar cell in Example 3.

### Example 4

An AlN single crystal layer was formed as the buffer layer on the c-plane of a sapphire substrate by the RF sputtering method. A layer made of GaN, which is a group III nitride semiconductor, was formed as the base layer 14a on the buffer layer by the MOCVD method.

Specifically, the c-plane (0001) of sapphire substrate, which was mirror-polished and had a diameter of two inches, was introduced into a chamber in the high frequency sputtering device. An Al metal was used as a target.

The substrate was heated to 500° C. in the chamber, then nitrogen gas was introduced. After that, high frequency bias was applied to the side of the substrate. The surface of the substrate was cleaned by subjected with nitrogen plasmas.

Subsequently, while the temperature of the substrate was maintained at 500° C., argon gas and nitrogen gas were introduced into the sputter device. After that, high frequency bias was applied to the side of a metal Al target, and the pressure inside the chamber was maintained to 0.5 Pa. Then, the buffer layer made of AlN single crystal was laminated on the sapphire substrate by flowing a certain amount of Ar gas and nitrogen gas through the chamber.

After layering the buffer layer, plasma operation was stopped, and the temperature of the substrate was fallen.

Then, the x-ray rocking curve (XRC) of the buffer layer on the substrate was measured using an x-rays measuring device (Spectris Co., PANalytical; Model Number: X′ Pert Pro MRD) and a Cu-Kα ray-X ray generation source as the light source. The XRC spectral half bandwidth of the buffer layer was 0.1°. It was confirmed that the buffer layer was oriented under good conditions.

After that, the substrate having the buffer layer was removed from the sputtering device, and put into the MOCVD device. The base layer made of GaN was formed on the buffer layer as follows.

Specifically, the substrate was put into a reaction furnace, that is, the MOCVD device. After introducing nitrogen gas in the reaction furnace, the temperature of the substrate was rised from room temperature to 500° C. While maintaining the temperature of the substrate to 500° C., NH₃ gas and nitrogen gas were passed through the furnace, and the pressure in the furnace was adjusted to 95 kPa. Subsequently, the temperature of the substrate was rised to 1,000° C., and the surface of the substrate was thermally cleaned. After thermal cleaning, nitrogen gas was supplying into the furnace.

While supplying NH₃ gas, the temperature of the substrate was rised to 1,100° C. under hydrogen atmosphere, and the pressure inside the furnace was adjusted to 40 kPa. After confirming that the temperature of the substrate was stable at 1,100° C., trimethyl gallium (TMG) was started to supply in the furnace. Thereby, the base layer made of GaN, which is a group III nitride compound semiconductor, was started to form on the buffer layer. After growing GaN, the valve in a pipe for introducing TMG was switched. Thereby, supplying the raw material into the furnace was stopped to stop growth of GaN.

During these processes, the base layer, which has a thickness of 8 μm, and made of undoped GaN, was layered on the buffer layer made of single crystal AlN.

After that, the laminate was produced in a similar way to Example 1. Specifically, the dopant layer, which contains sprinkled crystalline Si aggregations in an island shaped and has a thickness of 2 nm, and the undoped GaN layer having a thickness of 100 nm were repeatedly layered forty times. Thereby, the n-type GaN layer 50 having a thickness of about 0.5 μm was obtained. In addition, the dopant layer, which contains sprinkled crystalline Mg aggregations in an island shaped, and has a thickness of 2 nm, and the undoped GaN layer having a thickness of 100 nm were repeatedly layered forty times. Thereby, the p-type GaN layer 51 having a thickness of about 0.5 μm was obtained.

Moreover, the IZO film was thermally treated at 800° C. for one minute under N₂ atmosphere. Thereby, the IZO film containing hexagonal In₂O₃ crystal was produced.

The solar cell was obtained using the obtained laminate in Example 4.

### Example 5

The solar cell was obtained in a manner identical to that of Example 3 of the present invention, except that X1 in the n-type and p-type Inₓ₁Ga₁₋ₓ₁N layers was changed from 0.09 to 0.06.

The solar cell in a size of 1 cm×1 cm, which was prepared in Examples 1 to 5 was arranged on a sample stage. A probe was contacted with the positive electrode and the negative electrode of the lead frame to form a circuit for measuring the current and the voltage. The output characteristics were measure by irradiating pseudo 1 sun light having a spectrum distribution of AM 1.5 and an energy density of 100 mW/cm² using a solar simulator marketed by Yamashita Denso Corporation under conditions the temperature of the atmosphere the solar cell was adjusted to 25° C.±1° C. The obtained results are shown in Table 1.

Moreover, light was irradiated from the substrate side during the measurements. Since the solar cell obtained Examples 1 to 5 include the translucent ohmic electrode, the solar cell sufficiently worked even when light was irradiated from the electrode side.

TABLE 1

| | | Open | Current | |
|---|---|---|---|---|
| | | voltage | density | Conversion |
| Example | Junction Structure | [V] | [mA/cm²] | efficiency |
| 1 | n-type GaN/p-type GaN | 2.7 | 1.2 | 2.4 |
| 2 | n-type GaN/p-type GaN | 2.6 | 1.1 | 2.0 |
| 3 | n-type Inₓ₁Ga₁₋ₓ₁N | 2.0 | 1.8 | 2.5 |
| | (X1 = 0.09)/ | | | |
| | p-type Inₓ₁Ga₁₋ₓ₁N | | | |
| | (X1 = 0.09) | | | |
| 4 | n-type GaN/p-type GaN | 2.8 | 1.3 | 2.6 |
| 5 | n-type Inₓ₁Ga₁₋ₓ₁N | 2.1 | 1.4 | 2.1 |
| | (X1 = 0.06)/ | | | |
| | p-type Inₓ₁Ga₁₋ₓ₁N | | | |
| | (X1 = 0.06) | | | |

### Evaluation Test 1: Relationship Between the Temperature in the Thermal Treatment for the IZO Film and the Sheet Resistance

In the Evaluation Test 1, the relationship between the temperature in the thermal treatment (annealing) for the IZO film and the sheet resistance was examined by the following manner.

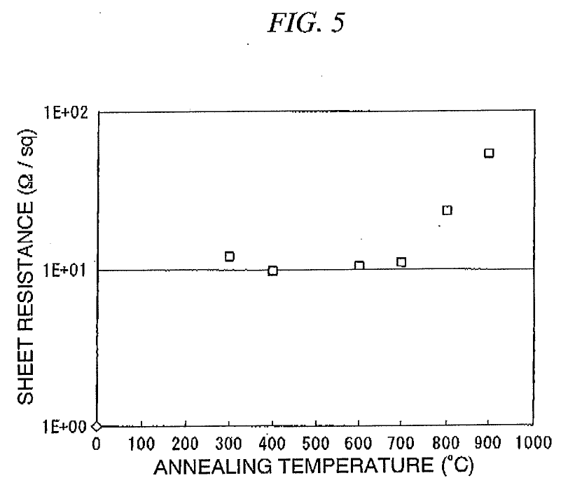

Specifically, the amorphous IZO film having a thickness of 250 nm was formed on the sapphire substrate. Then, the obtained IZO film was thermally treated at a temperature in a range of from 300° C. to 900° C. under N₂ atmosphere, and the sheet resistance was measured. The measurement results are shown in the following Table 2 and FIG. 5. Moreover, the sheet resistance was measured by a device using a four probe method (Trade name: Loresta MP MCP-360; marketed by Mitsubishi Chemical Corporation).

TABLE 2

| | | Conditions in annealing | | | Hall measurement | | | | | | | |
|---|---|---|---|---|---|---|---|---|---|---|---|---|
| | | (Conditions in the | | | | | | | Carrier | Sheet carrier | | |
| | Material | thermal treatment) | | | Temper- | Specific | Sheet | | concen- | concen- | | |
| | of the | Temperature | Atmos- | | ature | resistance | resistance | Hall | tration | tration | Mobility | Carrier |
| No. | substrate | (° C.) | phere | Device | (k) | (Ω · cm) | (Ω/sq.) | coefficient | (cm⁻³) | (cm⁻³) | (cm²/v · sec) | type |
| a | Sapphire | 300 | N₂ | RTA | 300 | 2.95E−04 | 11.8 | 8.5E−03 | 7.4E+20 | 1.8E+16 | 28.6 | N |
| b | Sapphire | 400 | N₂ | RTA | 300 | 2.40E−04 | 9.6 | 7.4E−03 | 8.4E+20 | 2.1E+16 | 30.9 | N |
| c | Sapphire | 600 | N₂ | RTA | 300 | 2.60E−04 | 10.4 | 1.0E−02 | 6.2E+20 | 1.6E+16 | 38.7 | N |
| d | Sapphire | 700 | N₂ | RTA | 300 | 2.69E−04 | 10.8 | 1.3E−02 | 4.7E+20 | 1.2E+16 | 49.5 | N |
| e | Sapphire | 800 | N₂ | RTA | 300 | 5.78E−04 | 23.1 | 2.0E−02 | 3.1E+20 | 7.7E+15 | 35.0 | N |
| f | Sapphire | 900 | N₂ | RTA | 300 | 1.33E−03 | 53.2 | 4.1E−02 | 1.5E+20 | 3.8E+15 | 30.9 | N |

As shown in Table 2 and FIG. 5, the sheet resistance was about 10 Ω/sq. when the IZO film was annealed under N₂ atmosphere at 700° C. or less. It was confirmed that the IZO film has extremely excellent properties. In contrast, when the IZO film was annealed at 800° C. the sheet resistance started to rise. When the IZO film was annealed at 900° C., the sheet resistance was 53.2 Ω/sq. From these results, it is clear that when the temperature in annealing exceeds 800° C., the sheet resistance suddenly increases. Moreover, the sheet resistance of the amorphous IZO film having a thickness of 250 nm before annealing was 15 Ω/sq.

### Evaluation Test 2: Relationship Between the Temperature in the Thermal Treatment for the IZO Film and the Concentration and Mobility of the Carrier

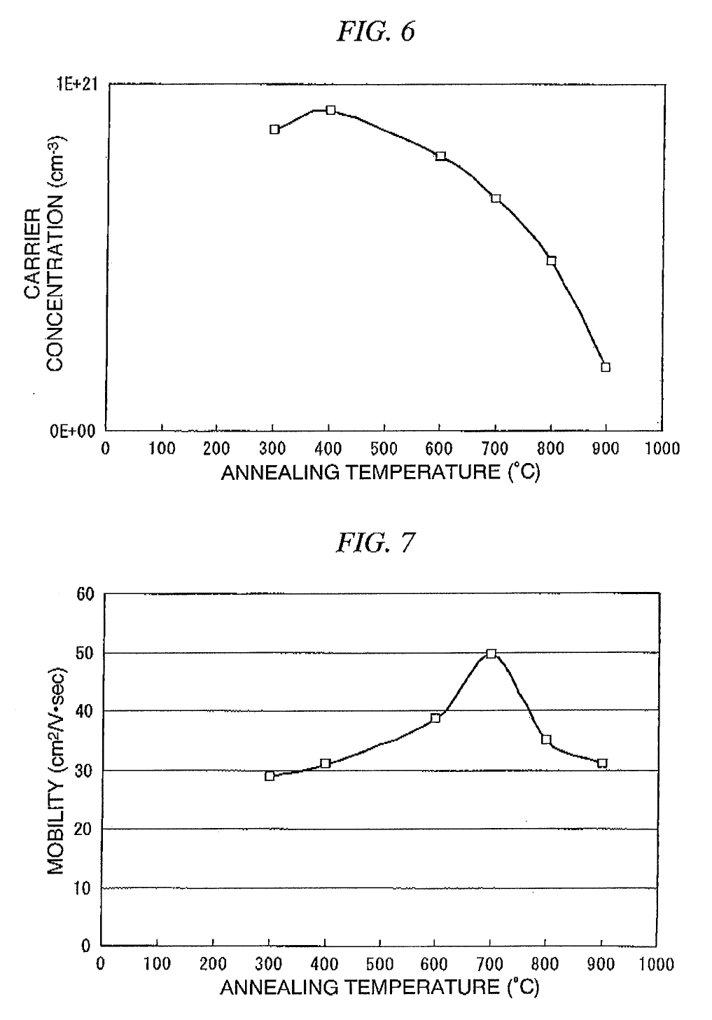

In the Evaluation Test 2, the concentration and mobility of the carriers in the IZO film produced in the Evaluation Test 1 was measure by the van del Pauw method. The results are shown in Table 2 and FIG. 6.

As shown in Table 2, the carrier concentration of the IZO film, which was annealed at 700° C., 800° C., and 900° C. under N₂ atmosphere, was 4.7×10²⁰, 3×10²⁰, and 1.5×10²⁰ cm⁻³. It is clear that when the annealing temperature increases, the carrier concentration decreases.

As shown in Table 2, the carrier mobility of the IZO film, which was annealed at 400° C., 600° C., 700° C., 800° C., and 900° C. under N₂ atmosphere, was 30.9, 38.7, 49.5, 35, and 30.9 cm²/V·sec. It is clear that when the annealing temperature is about 700° C., specifically, in a range of from 650 to 750° C., the carrier mobility is the largest. When the annealing temperature exceeds 800° C., the carrier mobility suddenly decreases.

Evaluation Test 3: Relationship Between the Temperature in the Thermal treatment for the IZO Film and the Crystalline Properties

In the Evaluation Test 3, the relationship between the temperature in the thermal treatment for the IZO and the crystalline properties of the IZO film was examined by the following manner.

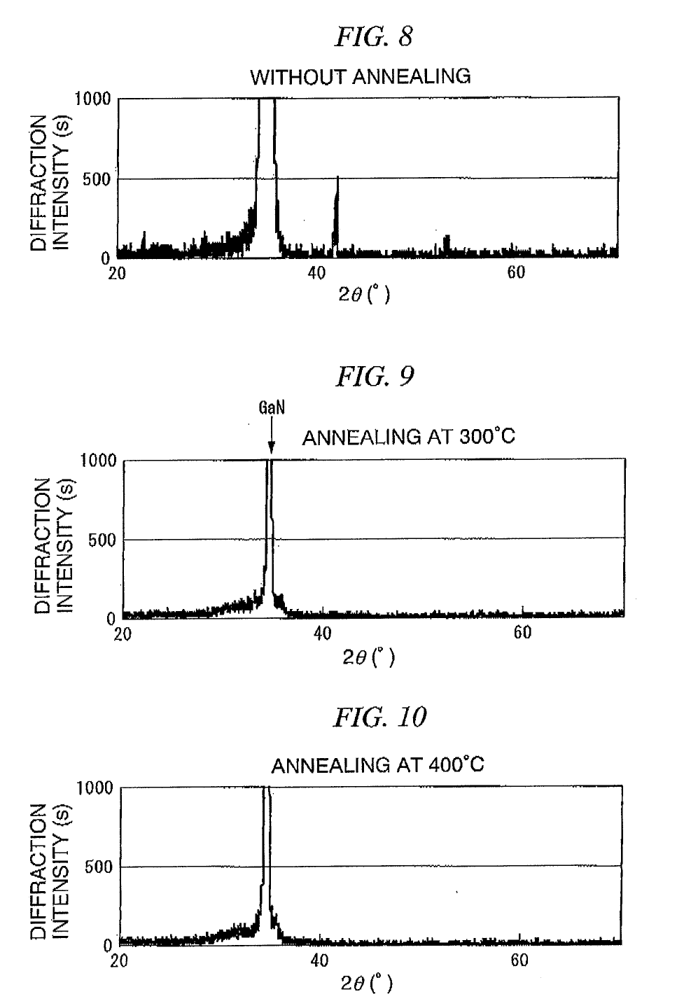

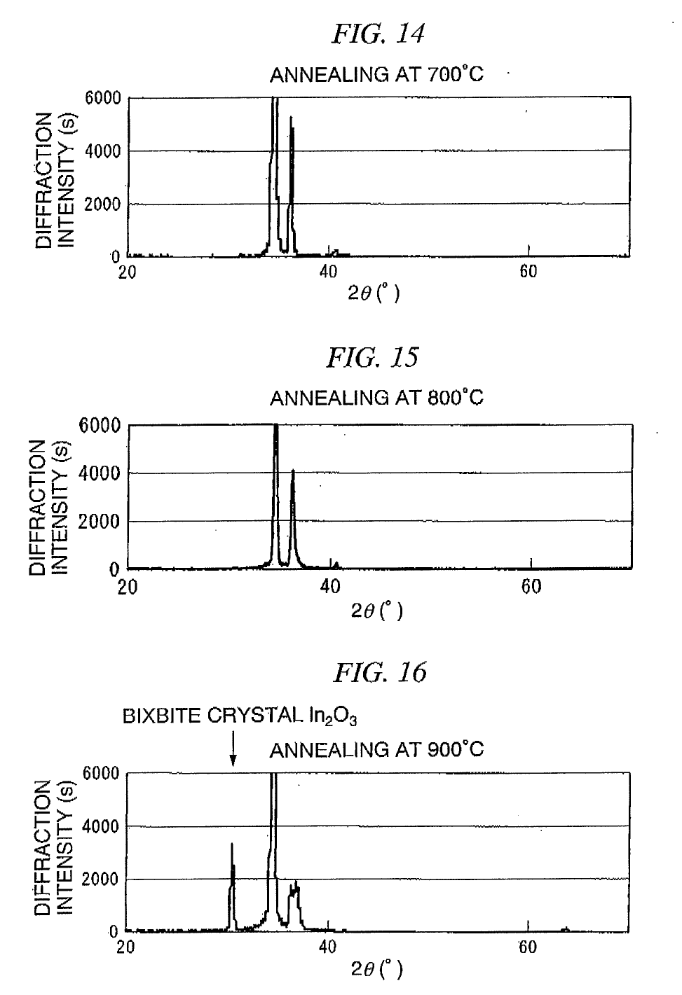

Specifically, the amorphous IZO film having a thickness of 250 nm was formed on the GaN epitaxial wafer, and the X-ray analysis data of the obtained IZO film without the thermal treatment was measured by the X-ray diffraction (ID) method. In addition, in a similar way to this, the amorphous IZO film having a thickness of 250 nm was formed on the GaN epitaxial wafer, and the obtained amorphous IZO film was thermally treated at a temperature in a range of from 300 to 900° C. for one minute under N₂ atmosphere. Then, the X-ray analysis data of the obtained IZO film, which was thermally treated, was measure by the X-ray diffraction (XRD) method. The results are shown in FIG. 8 to FIG. 16.

The X-ray diffraction data shows the crystalline properties of the IZO film.

As explained above, FIG. 8 to FIG. 16 show the X-ray diffraction data of the IZO film, and the horizontal axis shows a diffraction angle (2θ(°)), and the vertical axis shows a diffraction intensity(s).

As shown in FIG. 8 to FIG. 10, it was confirmed that the IZO film before the thermal treatment and the IZO film, which was thermally treated at 300° C. or 400° C., have a broad peak, which shows that the IZO film is an amorphous. It is clear from these results that the IZO film, which was thermally treated at 400° C. or less, is an amorphous.

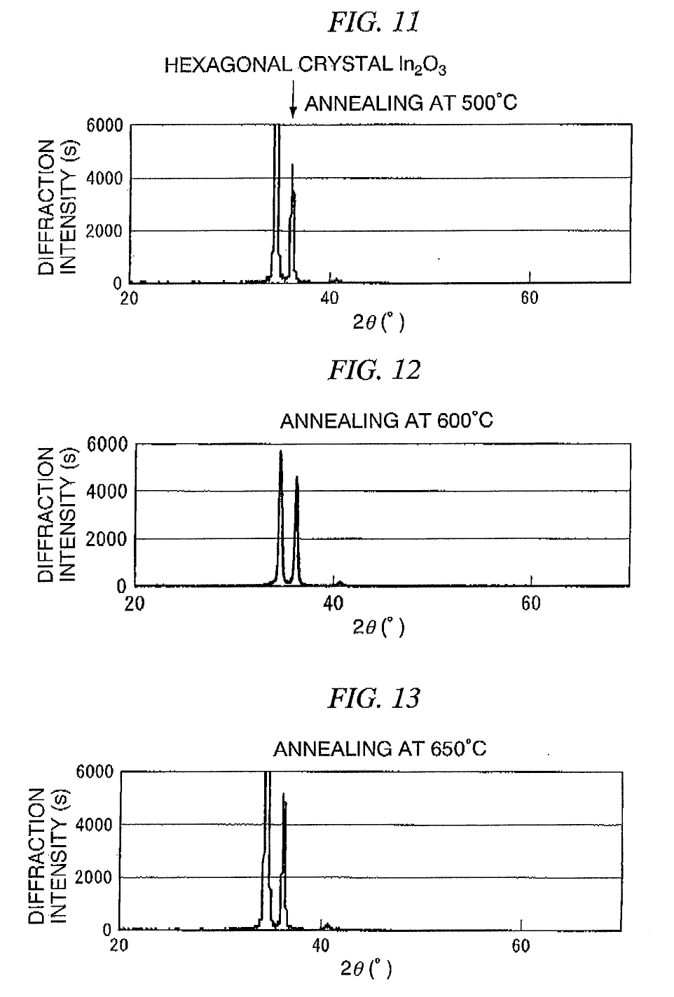

As shown in FIG. 11 to FIG. 15, it was confirmed that the IZO film, which was thermally treated at 500° C. to 800° C., has a peak, which shows that the IZO film is crystallized. It is clear from these results that the IZO film, which was thermally treated at 500° C. to 800° C., is crystallized.

As shown in FIG. 12 to FIG. 14, it was confirmed that the IZO film, which was thermally treated at 600° C., 650° C., and 700° C., have an extremely high peak. It was confirmed that the IZO film, which was thermally treated at 600° C. to 700° C., contains hexagonal In₂O₃ crystal.

As shown in FIG. 16, it was confirmed that the IZO film, which was thermally treated at 900° C., has a peak which shows that the IZO film has a bixbite structure. The peak was not recognized in the IZO film which was thermally treated at 800° C. or less. It was confirmed that the crystalline structure in the IZO film, which was thermally treated at 900° C., changed from a hexagonal structure to a bixbite structure.

### Evaluation Test 4: Relationship Between the Temperature in the Thermal Treatment for the IZO Film and the Light Transmittance

In the Evaluation Test 4, the relationship between the temperature in the thermal treatment for the IZO and the light transmittance was examined by the following manner.

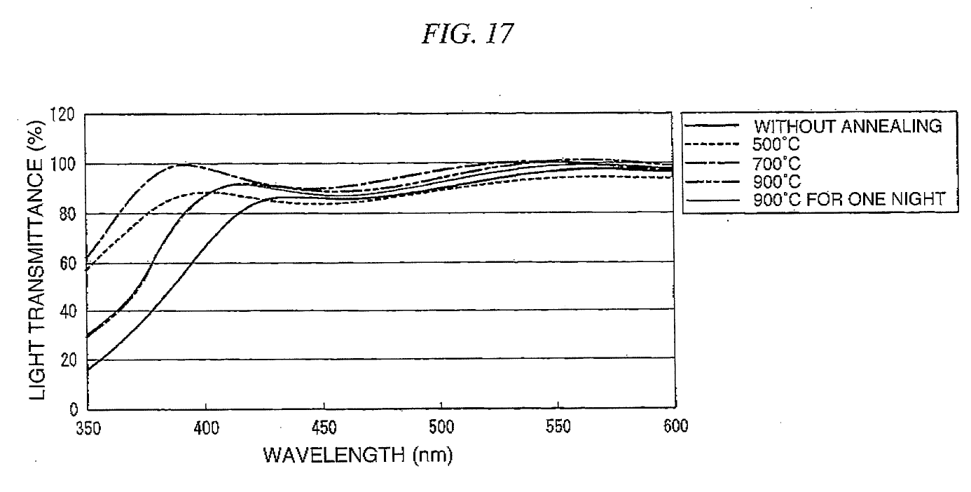

Specifically, the amorphous IZO film having a thickness of 250 nm was formed on the sapphire substrate. Then, the IZO film was thermally treated at 500° C., 700° C., and 900° C. After that, the light transmittance of the IZO film which was not thermally treated, and was thermally treated at 500° C., 700° C., and 900° C., was measured. The results are shown in FIG. 17.

Moreover, the light transmittance of the IZO film was measured using an ultraviolet-visible spectral photometer UV-2450, marketed by Shimazu Corporation. In addition, the light transmittance was evaluated by subtract the light transmittance of the sapphire substrate from the measured value.

FIG. 17 shows the light transmittance of the IZO film, and the horizontal axis shows a wavelength (nm), and the vertical axis shows a light transmittance (%).

As shown in FIG. 17, it is clear that the IZO film, which was thermally treated at 700° C., has light transmittance, which is higher than that of the IZO film, which was not thermally treated or was thermally treated at other temperatures. In particular, it is recognized that the IZO film, which was thermally treated at 700° C., has high light transmittance around 400 nm in ultraviolet ray range, and around 460 nm in blue light emitting range.

In contrast, it is also recognized that the light transmittance of the IZO film, which was thermally treated at 900° C., was not sufficiently improved. Therefore, it is clear that the temperature in the thermal treatment be preferably in a range of from 500 to 800° C., and more preferably in a range of from 650 to 700° C.

### Evaluation Test 5: Relationship Between the Temperature in the Thermal Treatment for the ITO Film and the Crystalline Properties

In the Evaluation Test 5, the relationship between the temperature in the thermal treatment for the ITO and the crystalline properties of the ITO film was examined, in a similar way to the Evaluation Test 3.

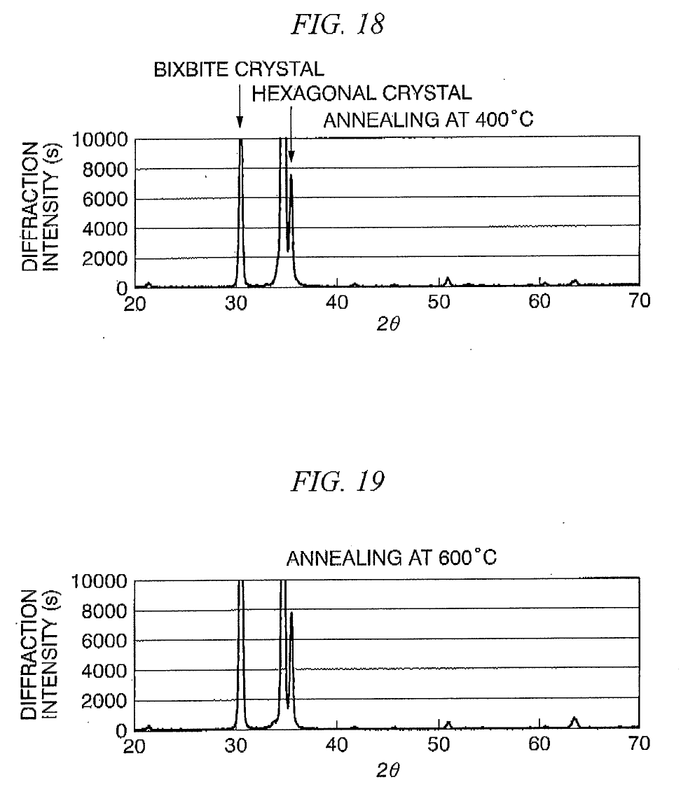

Specifically, the amorphous ITO film having a thickness of 250 nm was formed on the GaN epitaxial wafer. Then, the obtained amorphous ITO film was thermally treated at a temperature at 400° C. or 600° C. for one minute under N₂ atmosphere. Then, the X-ray analysis data of the obtained ITO film was measure by the X-ray diffraction (XRD) method. The results are shown in FIG. 18 and FIG. 19.

Moreover, the horizontal axis shows a diffraction angle (2θ(°)), and the vertical axis shows a diffraction intensity(s) in FIG. 18 and FIG. 19.

As shown in FIG. 18 to FIG. 19, it was confirmed that the ITO film, which was thermally treated at 400° C. or 600° C., has a peak, which shows that the ITO film contains hexagonal In₂O₃ crystal, and a peak, which shows that the ITO film contains bixbite In₂O₃ crystal. It is clear from these results that the ITO film contains hexagonal In₂O₃ crystal by the thermal treatment at temperatures in a range of from 400 to 600° C.

In addition, the sheet resistance in the ITO film was 15 Ω/sq.

### Evaluation Test 6: Relationship Between the Temperature in the Thermal Treatment for the IGO Film and the Crystalline Properties

In the Evaluation Test 6, the relationship between the temperature in the thermal treatment for the IGO and the crystalline properties of the IGO film was examined, in a similar way to the Evaluation Test 3.

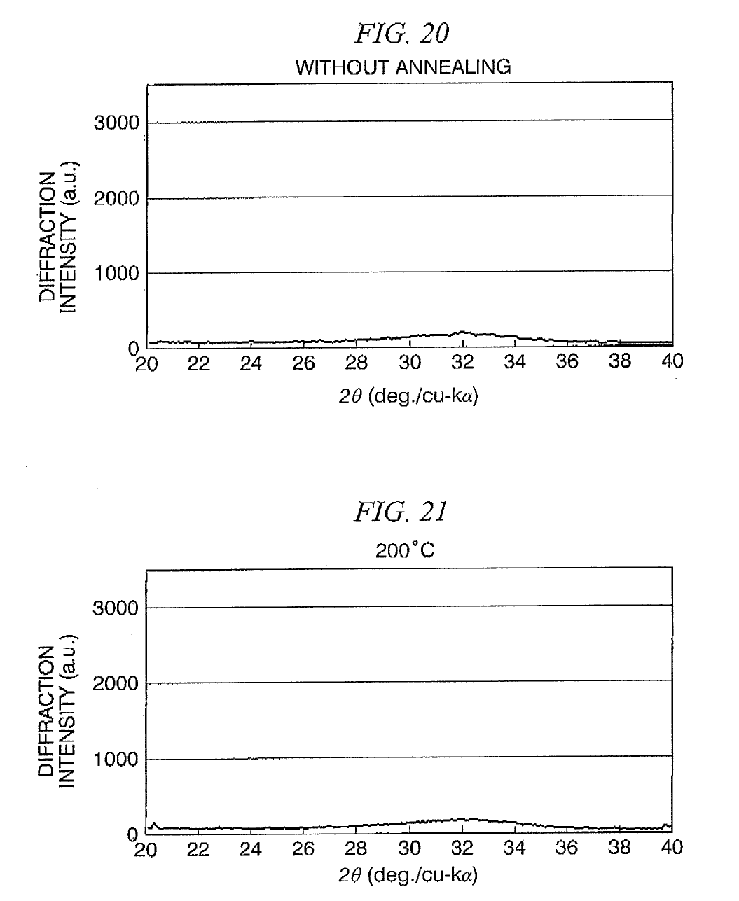

Specifically, the amorphous IGO film having a thickness of 250 nm was formed on the GaN epitaxial wafer. Then, the obtained amorphous IGO film was thermally treated at a temperature at 200° C., 400° C. or 600° C. for one minute under N₂ atmosphere. Then, the X-ray analysis data of the obtained IGO film, which was not thermally treated, and was thermally treated, was measure by the X-ray diffraction (XRD) method. The results are shown in FIG. 20 to FIG. 23.

Moreover, the horizontal axis shows a diffraction angle (2θ(°)), and the vertical axis shows a diffraction intensity(s) in FIG. 20 to FIG. 23.

As shown in FIG. 20 to FIG. 21, it was confirmed that the IGO film, which was not thermally treated or thermally treated at 200° C., has a broad peak, which shows that the IGO film is amorphous.

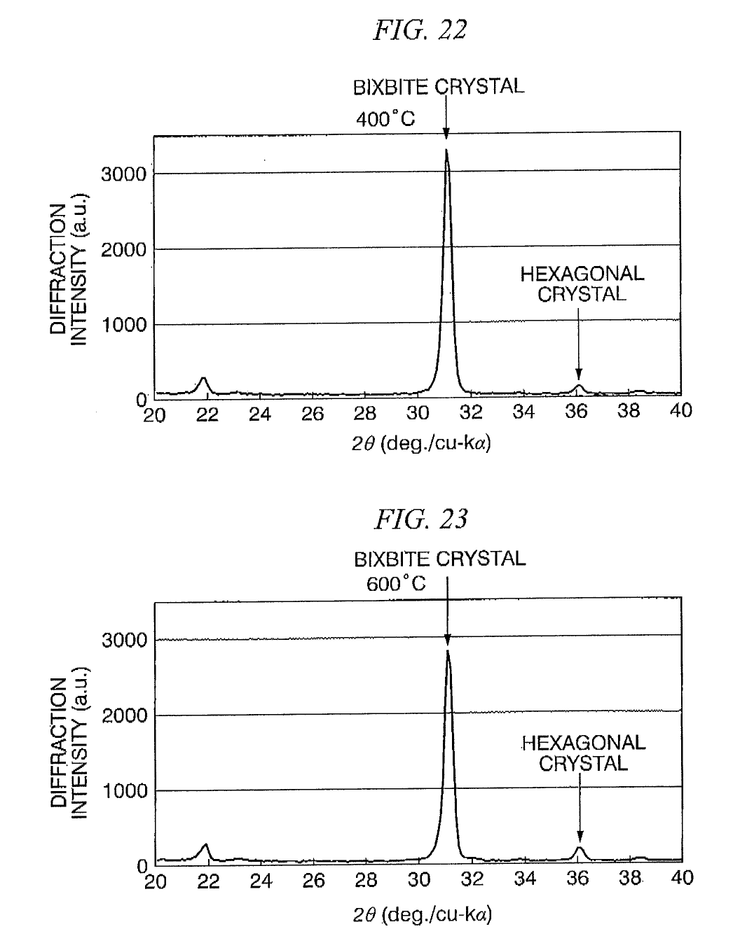

In addition, as shown in FIG. 22 and FIG. 23, the IGO film, which was thermally treated at 400° C. or 600° C., has a peak which shows the IGO film contains hexagonal In₂O₃ crystal, and a peak, which shows that the IGO film contains bixbite In₂O₃ crystal. It is clear from these results that the IGO film contains hexagonal In₂O₃ crystal by the thermal treatment at temperatures in a range of from 400 to 600° C.

In addition, the sheet resistance in the IGO film was 40 Ω/sq.

Based on the results of the Evaluation Tests, it is clear that the IZO film, the ITO film, and the IGO film are preferably used as a material for an electrode in a solar cell, in particular, the material for the translucent electrode.

What is claimed is:

1. A solar cell comprising a substrate,
a power generation layer for converting received light into electrical power,
a translucent electrode, and
another electrode which forms a pair with the translucent electrode,
wherein when light travels through each member from a first surface thereof, a surface opposite to the first surface is defined as a second surface,
the power generation layer is formed at a second surface side of the substrate,
the translucent electrode is formed on one surface of the power generation layer, and
the another electrode is formed on the other surface of the power generation layer,
wherein the translucent electrode comprises hexagonal In₂O₃ crystal.

2. A solar cell according to claim 1, wherein the hexagonal In₂O₃ crystal is comprised in crystalline IZO, and the content of zinc in the crystalline IZO is in a range of from 1% by mass to 20% by mass as a ZnO equivalent.

3. A solar cell according to claim 1, wherein a thickness of the translucent electrode is in a range of from 35 nm to 10 μm.

4. A solar cell according to claim 1, wherein the power generation layer comprises a group III nitride semiconductor layer having a pn-junction, which includes a p-type group III nitride semiconductor layer and an n-type group III nitride semiconductor layer, on the second surface side of the substrate.

5. A solar cell according to claim 1, wherein the power generation layer comprises a group III nitride semiconductor layer having a pn-junction, a p-type group III nitride semiconductor layer and an n-type group In nitride semiconductor layer,
wherein the power generation layer is formed on a buffer layer, which is made of a group III nitride semiconductor,
the buffer layer is formed at the second surface side of the substrate, and
at least one of the buffer layer and the group III nitride semiconductor layer has a compound semiconductor layer which is made by a sputtering method.

6. A solar cell according to claim 5, wherein the power generation layer comprises plural pn-junctions made of group III nitride semiconductor layers with p-type layers and n-type layers.

7. A solar cell according to claim 5, wherein the group III nitride semiconductor layer having a pn-junction is formed on the buffer layer, and the group III nitride semiconductor layer having a pn-junction is made of InₓGa₍₁₋ₓ₎N (0≦x<1).

8. A solar cell according to claim 1, wherein the substrate is a substrate made of at least one of quartz, glass, sapphire, SiC, silicon, zinc oxide, magnesium oxide, manganese oxide, zirconium oxide, manganese-zinc-iron oxide, magnesium-aluminum oxide, zirconium boride, gallium oxide, indium oxide, lithium-gallium oxide, lithium-aluminum oxide, neodymium-gallium oxide, lanthanum-strontium-aluminum-tantalum oxide, strontium-titanium oxide, and titanium oxide.

9. A solar cell according to claim 1, wherein a p-type electrode of the translucent electrode and an n-type electrode of the another electrode are formed partially or entirely on the group III nitride semiconductor layer having a pn-junction.

10. A solar cell according to claim 5, wherein the buffer layer is made of AlN or GaN.

11. A method for producing a solar cell comprising:
wherein when light travels through each member from a first surface thereof, a surface opposite to the first surface is defined as a second surface,
the method comprising:
a step (a) for forming a power generation layer for converting light received into electrical power at a second surface side of the substrate;
a step (b) for forming an electrode on a surface of the power generation layer; and
a step (c) for forming a translucent electrode, which forms a pair with the electrode, at another surface of the power generation layer,
wherein the step (c) comprises:
a step (c1) for layering an amorphous IZO (indium-zinc-oxide) film at a side of a p-type semiconductor layer which is included in the power generation layer;
a step (c2) for etching the amorphous IZO film, and
a step (c3) for thermally treating the etched amorphous IZO film to be crystallized.

12. A method for producing a solar cell according to claim 11, wherein the step (c1) is carried by the sputtering method.

13. A method for producing a solar cell according to claim 12, wherein a temperature in the step (c3) is in a range of from 500 to 1,000° C.

14. A method for producing a solar cell according to claim 11, wherein the power generation layer is made of a nitride gallium based compound semiconductor which is a group III nitride semiconductor.

15. A method for producing a solar cell according to claim 14, wherein the amorphous IZO film is layered on the p-type semiconductor layer in the power generation layer.

16. A method for producing a solar cell according to claim 11,
wherein the step (a) comprises a step for forming at least one of the buffer layer and the III nitride semiconductor layer having a pn-junction by the sputtering method,
the buffer layer is formed on the substrate and made of a group III nitride semiconductor, and
the III nitride semiconductor layer having a pn-junction (n-type layer and p-type layer) is formed on the buffer layer.

17. A method for producing a solar cell according to claim 16, wherein any one layer of the p-type group III nitride semiconductor layer and the n-type group III nitride semiconductor layer is formed by at least one method selected from the group consisting of a sputtering method, MOCVD method, MBE method, CBE method, and MLE method.

18. A method for producing a solar cell according to claim 16, wherein the sputtering method is a method in which nitrogen in the state of plasma, radical, and atom is supplied to react with a group III element.

19. A method for producing a solar cell according to claim 16, wherein the method include a first step for alternately repeating a process for supplying only a dopant element and a process for supplying simultaneously a compound including a group III element and a nitrogen material.

20. A method for producing a solar cell according to claim 19, wherein the method comprises a second step for a thermal treatment after the first step.

21. A method for producing a solar cell according to claim 20, wherein the temperature in the thermal treatment is in the range of from 300 to 1,200° C.

22. A method for producing a solar cell according to claim 20, wherein the thermal treatment is carried out under an atmosphere which does not contain a hydrogen gas or a gas containing compounds having a hydrogen atom.

23. A method for producing a solar cell according to claim 19, wherein the dopant element is at least one selected from the group consisting of Si, Ge, and Sn.

24. A method for producing a solar cell according to claim 19, wherein the dopant element is at least one selected from the group consisting of Mg, and Zn.
